(19) United States
(12) Patent Application Publication
(10) Pub. No.: US 2026/0164954 A1
(43) Pub. Date: Jun. 11, 2026

(54) DISPLAY DEVICE, METHOD OF MANUFACTURING THE DISPLAY DEVICE, AND ELECTRONIC APPARATUS INCLUDING THE DISPLAY DEVICE

(71) Applicant: Samsung Display Co., Ltd., Yongin-si (KR)

(72) Inventors: SUNGHWAN KIM, Yongin-si (KR); HEYJIN SHIN, Yongin-si (KR)

(21) Appl. No.: 19/394,454

(22) Filed: Nov. 19, 2025

(30) Foreign Application Priority Data
Dec. 10, 2024 (KR) 10-2024-0182958

(51) Int. Cl. H10K 59/124; H10K 59/12; H10K 59/122; H10K 59/131; H10K 102/00

(52) U.S. Cl. CPC H10K 59/124; H10K 59/1201; H10K 59/122; H10K 59/131; H10K 2102/351

(57) ABSTRACT

A display device, a method for manufacturing the display device, and an electronic apparatus including the display device are provided. A display device includes a substrate having a display area and a peripheral area outside the display area, a first insulating layer which is on a first connection electrode on the substrate and is in the display area as well as the peripheral area on the substrate, a second connection electrode on the first insulating layer, a second insulating layer on the second connection electrode, a third insulating layer on the second insulating layer, and a third connection electrode on the third insulating layer.

### CROSS-REFERENCE TO RELATED APPLICATION

The present application claims priority to and the benefit of Korean Patent Application No. 10-2024-0182958, filed on Dec. 10, 2024, in the Korean Intellectual Property Office, the entire disclosure of which is incorporated herein by reference.

### BACKGROUND

### 1. Field

One or more embodiments relate to a display device, a method of manufacturing the display device, and an electronic apparatus including the display device.

### 2. Description of the Related Art

As the demand for display devices increases, there is a growing need for such display devices to be utilized for various purposes requiring different configurations. In line with this trend, display devices are becoming increasingly larger and thinner. Furthermore, there is a growing need for display devices that offer accurate and vivid colors.

### SUMMARY

Aspects of one or more embodiments of the present disclosure are directed toward a display device with improved optical characteristics, a method for manufacturing the display device, and an electronic apparatus including the display device.

Additional aspects one or more embodiments of the present will be set forth in part in the description which follows and, in part, will be apparent from the description, or may be learned by practice of the presented embodiments of the present disclosure.

According to one or more embodiments, a display device includes a substrate having a display area and a peripheral area arranged outside the display area, a first insulating layer which is arranged on a first connection electrode arranged on the substrate and is arranged in the display area as well as the peripheral area on the substrate, a second connection electrode arranged on the first insulating layer, a second insulating layer arranged on the second connection electrode, a third insulating layer arranged on the second insulating layer, and a third connection electrode arranged on the third insulating layer.

In one or more embodiments, the third insulating layer may be a planarizing layer.

In one or more embodiments, the display device may further include a fourth insulating layer arranged on the third insulating layer.

In one or more embodiments, the fourth insulating layer may be a planarizing layer.

In one or more embodiments, the third insulating layer may further include a pixel-defining layer having at least two openings defined therein.

In one or more embodiments, the display device may further include a first pixel electrode of which a central portion is exposed by one opening of the at least two openings of the pixel-defining layer and which is arranged above the third insulating layer, and a second pixel electrode of which a central portion is exposed by another opening of the at least two openings of the pixel-defining layer and which is arranged above the third insulating layer. At least a portion of the first pixel electrode is in contact with the third insulating layer, and the second pixel electrode is not to be in contact with the third insulating layer.

In one or more embodiments, the pixel-defining layer may be a black pixel-defining layer.

For example, in one or more embodiments, a display device includes a substrate with a display area and a peripheral area, multiple insulating layers, and connection electrodes arranged on the substrate. The third insulating layer may serve as a planarizing layer, and the device may also include a fourth insulating layer, which can also be a planarizing layer. The third insulating layer may further include a pixel-defining layer with at least two openings, exposing central portions of first and second pixel electrodes. The first pixel electrode is in contact with the third insulating layer, while the second pixel electrode is not. The pixel-defining layer may be a black pixel-defining layer.

According to one or more embodiments, a display device includes a substrate having a display area and a peripheral area arranged outside the display area, a first insulating layer which is arranged on a first connection electrode arranged on the substrate and is arranged in the display area as well as the peripheral area on the substrate, a second connection electrode arranged on the first insulating layer, a second insulating layer arranged on the second connection electrode, a third insulating layer arranged on the second insulating layer and formed to be planarized, a pixel-defining layer arranged on the third insulating layer and having at least two openings defined therein, and a first pixel electrode and a second pixel electrode of which central portions are exposed by the least two openings.

In one or more embodiments, a thickness of an insulating layer positioned at a position overlapping a portion at which the first pixel electrode is exposed may be different from a thickness of the insulating layer positioned at a position overlapping a portion at which the second pixel electrode is exposed.

In one or more embodiments, at least a portion of the first pixel electrode may be in contact with the third insulating layer.

In one or more embodiments, the display device may further include an emission layer arranged on the first pixel electrode and configured to emit green light.

In one or more embodiments, the second pixel electrode may be positioned not to be in contact with the third insulating layer.

In one or more embodiments, the display device may further include an emission layer arranged on the second pixel electrode and configured to emit red or blue light.

In one or more embodiments, the display device may further include a third connection electrode arranged on the third insulating layer, and a fourth insulating layer arranged on the third connection electrode.

In one or more embodiments, the fourth insulating layer may be a planarizing layer.

For example, in one or more embodiment, a display device includes a substrate with a display area and a peripheral area, multiple insulating layers, and connection electrodes arranged on the substrate. The third insulating layer is planarized, and a pixel-defining layer with at least two openings is disposed on it, exposing central portions of first and second pixel electrodes. The thickness of the insulating layer varies depending on the position of the pixel electrodes. The first pixel electrode is in contact with the third insulating layer, while the second pixel electrode is not. Emission layers configured to emit green, red, or blue light are disposed on the pixel electrodes. Additionally, the device includes a third connection electrode and a fourth insulating layer, which may also be planarized.

According to one or more embodiments, a method for manufacturing a display device includes preparing a substrate, forming a first connection electrode on the substrate, forming a first insulating layer on the first connection electrode, forming a second connection electrode on the first insulating layer, forming a second insulating layer on the second connection electrode, forming a third insulating layer on the second insulating layer, and forming a third connection electrode on the third insulating layer.

In one or more embodiments, the forming of the third insulating layer may include planarizing the third insulating layer.

In one or more embodiments, the method may further include forming a fourth insulating layer on the third connection electrode.

In one or more embodiments, the method may further include forming a first pixel electrode and a second pixel electrode on the fourth insulating layer, and forming a pixel-defining layer having openings configured to expose central portions of the first pixel electrode and the second pixel electrode.

In one or more embodiments, a distance from an uppermost portion of the pixel-defining layer to a portion at which the first pixel electrode is exposed may be different from a distance from the uppermost portion of the pixel-defining layer to a portion at which the second pixel electrode is exposed.

For example, in one or more embodiments, a method for manufacturing a display device includes preparing a substrate, forming a first connection electrode on the substrate, and subsequently forming a first insulating layer, a second connection electrode, a second insulating layer, a third insulating layer, and a third connection electrode on the substrate. The third insulating layer may be planarized, and a fourth insulating layer may be formed on the third connection electrode. Additionally, the method includes forming first and second pixel electrodes on the fourth insulating layer and a pixel-defining layer with openings that expose the central portions of the pixel electrodes. The distance from the uppermost portion of the pixel-defining layer to the exposed portions of the first and second pixel electrodes may vary.

According to one or more embodiments, an electronic apparatus includes a controller configured to generate a scan input signal, a power module (e.g., a power supply) configured to generate a scan input voltage, and a display device partitioned into a display area in which a pixel circuit is arranged (e.g., is located) and a peripheral area positioned outside the display area and including a pad area, where the display device includes a substrate having a display area and a peripheral area arranged outside the display area, a first insulating layer which is arranged on a first connection electrode arranged on the substrate and is arranged in the display area as well as the peripheral area on the substrate, a second connection electrode arranged on the first insulating layer, a second insulating layer arranged on the second connection electrode, a third insulating layer arranged on the second insulating layer, and a third connection electrode arranged on the third insulating layer.

### BRIEF DESCRIPTION OF THE DRAWINGS

These and/or other aspects will become apparent and more readily appreciated from the following description of one or more embodiments, taken in conjunction with the accompanying drawings in which:

FIG. 1 is a schematic plan view illustrating a part of a display device according to one or more embodiments of the present disclosure;

FIG. 2 is a schematic enlarged plan view illustrating part A of the display device of FIG. 1;

FIG. 3 is an equivalent circuit diagram of one circuit included in the display device of FIG. 1;

FIG. 4 is a schematic layout illustrating emission areas of a plurality of pixels included in the display device of FIG. 1;

FIG. 5 is a cross-sectional view taken along the line I-I′ of FIG. 4;

FIG. 6 is a schematic enlarged view illustrating part B of FIG. 5;

FIG. 7 is a schematic enlarged view illustrating part C of FIG. 5;

FIGS. 8 and 9 are schematic conceptual views illustrating the cross-sectional view shown in FIG. 5; and

FIG. 10 is a schematic block diagram illustrating an example of an electronic apparatus according to one or more embodiments of the present disclosure.

### DETAILED DESCRIPTION

Because the present disclosure may apply one or more suitable transformations and have one or more suitable embodiments, one or more embodiments will be illustrated in the drawings and described in the detailed description. Effects and features of the present disclosure, and methods for achieving them will become clear with reference to one or more embodiments described in more detail together with the drawings. However, the present disclosure is not limited to one or more embodiments disclosed and may be implemented in one or more suitable forms.

In the following embodiments, it will be understood that if (e.g., when) a component such as a layer, film, area, or plate is referred to as being “on,” “formed on,” “formed above,” “positioned on,” “positioned above,” “disposed on,” “connected to,” “connected with,” or “coupled to” another layer, film, area, or plate, it can be directly or indirectly on, formed on, formed above, positioned on, positioned above, disposed on, connected to, connected with, or coupled to the other layer, film, area, or plate, such that one or more intervening components may be present therebetween. For example, when an element, layer, part, portion, region, or component is referred to as being “electrically connected” or “electrically coupled” to another element, layer, part, portion, region, or component, it can be directly electrically connected or coupled to the other element, layer, part, portion, region, or component, or intervening elements, layers, parts, portions, regions, or components may be present. However, “directly connected/directly coupled” refers to one component directly connecting or coupling another component without any intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present. For example, intervening layers, films, areas, or plates may be present. In addition, sizes of components in the drawings may be exaggerated or reduced for convenience of explanation.

It will be understood that, although the terms “first”, “second”, and/or the like do not have limited meaning but are utilized for the purpose of distinguishing one component from another component. The terms may be utilized herein to describe one or more suitable components, the components should not be limited by the terms. For example, without departing from the right scope of the present disclosure, a first component may be referred to as a second component, and similarly, the second component may also be referred to as the first component. Singular expressions include plural expressions unless clearly otherwise indicated in the context.

In the following embodiments, the expressions utilized in the singular such as “a,” “an,” and “the” are intended to include the plural forms as well, unless the context clearly indicates otherwise.

In the following embodiment, the expression “x direction” may refer to both (e.g., simultaneously) a +x direction and a −x direction, that is, a ±x direction. In the following embodiment, the expression “y direction” may refer to both (e.g., simultaneously) a +y direction and a −y direction, that is, a ±y direction. In the following embodiment, the expression “z direction” may refer to both (e.g., simultaneously) a +z direction and a −z direction, that is, a ±z direction. In the following embodiments, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

In the following embodiments, it will be understood that the terms such as “include/includes/including,” “comprise/comprises/comprising,” and “have/has/having” specify the presence of stated features integers, numbers, steps, operations, elements, and/or components, but do not preclude the presence or addition of one or more other features integers, numbers, steps, operations, elements, components, and/or groups thereof. Additionally, the terms “include/includes/including,” “comprise/comprises/comprising,” or “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the drawings, components may be exaggerated or reduced in size for convenience of description. For example, the sizes and/or thicknesses of the respective components shown in the drawings are arbitrarily shown for convenience of description, and thus one or more embodiments are not necessarily limited thereto.

Hereinafter, example embodiments of the present disclosure will be described in more detail with reference to the accompanying drawings, wherein like reference numerals refer to the same or corresponding components throughout the drawings, and a redundant description thereof will not be provided.

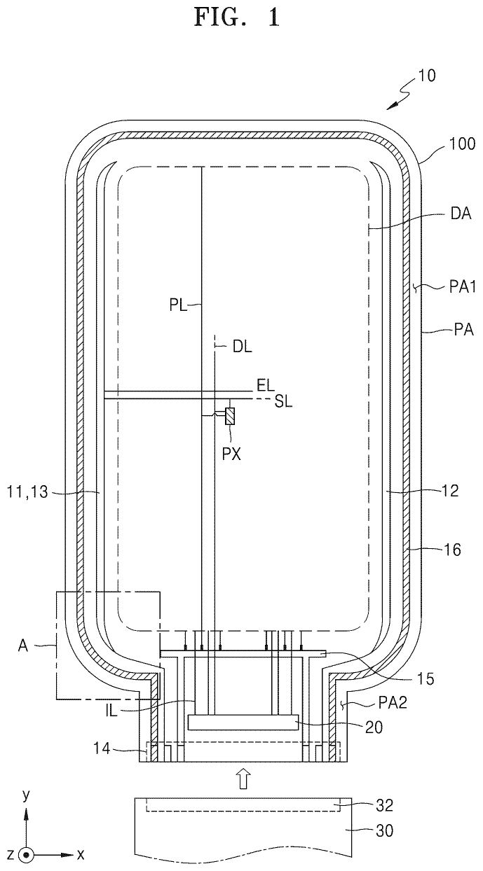

FIG. 1 is a schematic plan view illustrating a part of a display device according to one or more embodiments of the present disclosure. Referring to FIG. 1, the display device according to the present embodiment includes a display panel 10. Such a display device may be any device as long as the device includes the display panel 10. For example, the display device may be one or more suitable products such as a smartphone, a tablet, a laptop, a television, or a billboard.

The display panel 10 includes a display area DA and a peripheral area PA outside the display area DA. The display area DA may be an area in which an image is displayed, and a plurality of pixels may be arranged in the display area DA. If (e.g., when) viewed in a direction approximately normal (e.g., perpendicular) to the display panel 10, the display area DA may have one of one or more suitable shapes, such as a circular shape, an oval shape, a polygonal shape, and a specific shape. FIG. 1 illustrates that the display area DA has an approximately rectangular shape with round corners.

The peripheral area PA may be arranged outside the display area DA. The peripheral area PA may include a first peripheral area PA1 that surrounds at least a portion of one edge (in a −y direction or a −x direction) of the display area DA, and a second peripheral area PA2 positioned at one outer side of the display area DA (in the −y direction). The second peripheral area PA2 may be positioned adjacent to the first peripheral area PA1. For example, the second peripheral area PA2 may be positioned relatively closer to a center of the display panel 10 than the first peripheral area PA1 (e.g., in an x-axis direction). A width of the second peripheral area PA2 (e.g., in the x-axis direction) may be less than a width of the display area DA (e.g., in the x-axis direction). Through such a structure, as will be described in more detail, at least a portion of the second peripheral area PA2 may be suitably bent.

The display panel 10 may include a substrate 100, and the substrate 100 may have the display area DA and the peripheral area PA as described above. For convenience, it will be described that the substrate 100 has the display area DA and the peripheral area PA.

The display panel 10 may be bent about a bending axis (in the x-axis direction) in at least a portion of the second peripheral area PA2. If (e.g., when) the display panel 10 is bent in this way, a portion of the second peripheral area PA2 may be allowed to overlap the display area DA if (e.g., when) viewed in a z-axis direction. The present disclosure is not limited to bent display devices and may also be applied to non-bent display devices. The second peripheral area PA2 may be a non-display area. By bending the display panel 10 in this way, if (e.g., when) the display device is viewed from a front surface (in a −z direction), the non-display area may be prevented or reduced from being viewed, or an area of a visible portion may be minimized or reduced even if (e.g., when) the non-display area is viewed.

A driving chip 20 may be arranged in the second peripheral area PA2 of the display panel 10. The driving chip 20 may include an integrated circuit that drives the display panel 10. Such an integrated circuit may be a data driving integrated circuit that generates data signals, but the present disclosure is not limited thereto.

The driving chip 20 may be mounted in the second peripheral area PA2 of the display panel 10. The driving chip 20 may be mounted/located to be coplanar with a display surface of the display area DA. However, the display panel 10 may be bent in the second peripheral area PA2 as described above, and thus the driving chip 20 may be positioned on a rear surface of the display area DA (e.g., an area of the display area DA near the second peripheral area PA2).

A printed circuit board 30 and/or the like may be attached to an end portion of the second peripheral area PA2 of the display panel 10. The printed circuit board 30 and/or the like may be electrically connected to the driving chip 20 and/or the like through a pad on the substrate 100.

Hereinafter, an example in which an organic light-emitting display device is the display device according to one or more embodiments of the present disclosure will be described, but the display device of the present disclosure is not limited thereto. In one or more embodiments, the display device of the present disclosure may be an inorganic light-emitting display device (or an inorganic electroluminescence (EL) display device) or a display device such as a quantum dot light-emitting display device. For example, an emission layer of a display element included in the display device may include an organic material and/or an inorganic material. In one or more embodiments, the display device may also include an emission layer and quantum dots positioned on a path of light emitted from the emission layer.

As described above, the display panel 10 includes the substrate 100. One or more suitable components included in the display panel 10 may be positioned on the substrate 100. The substrate 100 may include glass, a metal, or a polymer resin. As described above, if (e.g., when) the display panel 10 is bent in the second peripheral area PA2, the substrate 100 needs to have flexible or bendable characteristics. In this case, the substrate 100 may include a polymer resin such as, for example, polyethersulphone (PES), polyacrylate (PAR), polyetherimide (PERI), polyethylene naphthalate, polyethylene terephthalate, polyphenylene sulfide, polyarylate, polyimide (PI), polycarbonate (PC), or cellulose acetate propionate (CAP). The substrate 100 may be suitably modified to have a multilayer structure and/or the like that includes two layers including polymer resin and a barrier layer including an inorganic material (such as silicon oxide, silicon nitride, silicon oxynitride, and/or the like) interposed between the two layers.

A plurality of pixels PX are positioned in the display area DA. Each of the pixels PX may refer to a subpixel and may include a display element such as an organic light-emitting diode (OLED) and a pixel circuit electrically connected to the display element. The pixel PX may be to emit, for example, red, green, blue, or white light. The pixel PX may be electrically connected to peripheral circuits arranged in the peripheral area PA. A first scan driving circuit 11, a second scan driving circuit 12, an emission control driving circuit 13, a terminal 14, a driving voltage supply line 15, and a common voltage supply line 16 may be arranged in the peripheral area PA.

The first scan driving circuit 11 may provide a scan signal to the pixel PX through a scan line SL. The second scan driving circuit 12 may be arranged parallel to the first scan driving circuit 11 with the display area DA arranged between the second scan driving circuit 12 and the first scan driving circuit 11. Some of the pixels PX arranged in the display area DA may be electrically connected to the first scan driving circuit 11, and others may be connected to the second scan driving circuit 12. If suitable, the second scan driving circuit 12 may not be provided, and all of the pixels PX arranged in the display area DA may be electrically connected to the first scan driving circuit 11.

The emission control driving circuit 13 may be arranged at the first scan driving circuit 11 and may provide an emission control signal to the pixel PX through an emission control line EL. The emission control driving circuit 13 may be arranged at only one side of the display area DA, but one or more embodiments are not limited thereto. The emission control driving circuit 13 may be arranged at each of opposite sides of the display area DA, e.g., at the first scan driving circuit 11 and the second scan driving circuit 12 of the display area DA.

The terminal 14 may be arranged in the second peripheral area PA2 of the substrate 100. The terminal 14 may be exposed without being covered by an insulating layer and thus may be electrically connected to the printed circuit board 30. A terminal 32 of the printed circuit board 30 may be electrically connected to the terminal 14 of the display panel 10.

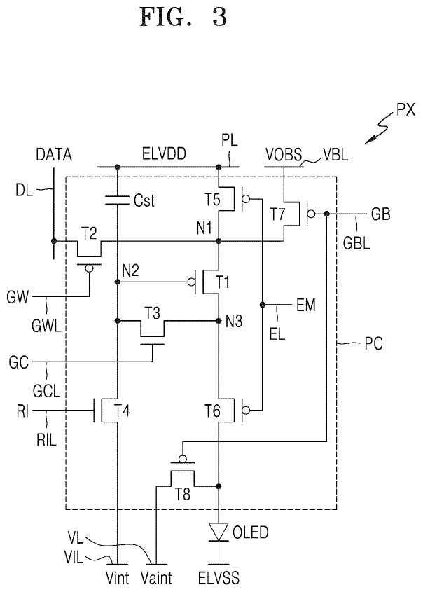

The printed circuit board 30 transmits signals or power of a control unit (e.g., a controller) to the display panel 10. The control signal generated by the control unit may be transmitted to each of the driving circuits 11, 12, and 13 through the printed circuit board 30. In one or more embodiments, the control unit may be to transmit a driving voltage ELVDD (see FIG. 3) to the driving voltage supply line 15 and may provide a common voltage ELVSS (see FIG. 3) to the common voltage supply line 16. The driving voltage ELVDD may be transmitted to each pixel PX through a driving voltage line PL connected to the driving voltage supply line 15, and the common voltage ELVSS may be transmitted to a counter electrode (common electrode) of the pixel PX connected to the common voltage supply line 16. The driving voltage supply line 15 may have a shape extending in one direction (for example, the x-axis direction) at a lower side of a second area DA2. The common voltage supply line 16 may have a loop shape of which one side is open and thus may have a shape that partially surrounds the display area DA.

In one or more embodiments, the control unit may generate a data signal, and the generated data signal may be transmitted to an input line IL through the driving chip 20 and may be transmitted to the pixel PX through a data line DL connected to the input line IL.

For reference, “line” may refer to “line” or “wire.” This also applies to one or more embodiments and modifications thereof described in more detail.

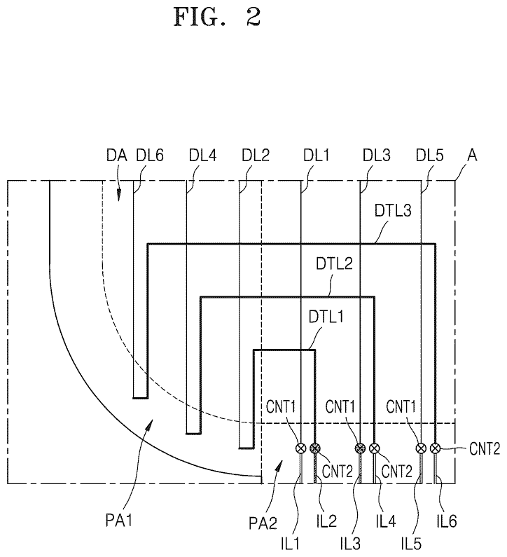

FIG. 2 is a schematic enlarged plan view illustrating part A of the display device of FIG. 1.

Referring to FIG. 2, one or more suitable signals may be applied to the display area DA. For example, a data signal and/or the like for controlling brightness of each pixel may be applied to the display area DA. To this end, as shown in FIG. 2, data lines DL1 to DL6, which are arranged in a first direction (e.g., in the x-axis direction) to be approximately parallel to each other and be extended in a second direction (e.g., the y-axis direction) intersecting (e.g., crossing) the first direction, may be positioned in the display area DA. If suitable, the data lines DL1 to DL6 may have a shape extending from the peripheral area PA to the inside of the display area DA as shown in FIG. 2. One or more suitable lines, such as power lines and scan lines, other than the data lines DL1 to DL6, may also be positioned inside and outside the display area DA.

First to sixth input lines IL1 to IL6 may be positioned in the peripheral area PA, for example, the second peripheral area PA2. The first to sixth input lines IL1 to IL6 may be connected to the driving chip 20 to receive data signals. First to sixth data lines DL1 to DL6 may be electrically connected to the first to sixth input lines IL1 to IL6 to transmit data signals to the pixels in the display area DA.

For convenience of description, FIG. 2 illustrates six input lines and six data lines. However, the present disclosure is not limited thereto, and the number of input lines and data lines may be greater than or equal to six.

The first to sixth input lines IL1 to IL6 may be sequentially arranged from an edge (e.g., in a direction of the first peripheral area PA1) of the second peripheral area PA2 toward a center of the second peripheral area PA2 (e.g., in a +x direction).

In one or more embodiments, the odd ordered input lines, the first input line IL1, the third input line IL3, and the fifth input line IL5, may be electrically connected to the first data line DL1, the third data line DL3, and the fifth data line DL5 which are consecutively arranged adjacent to each other. Each of the first input line IL1, the third input line IL3, and the fifth input line IL5 may be formed integrally with a corresponding one selected from among the first data line DL1, the third data line DL3, and the fifth data line DL5, or as shown in FIG. 2, each of the first input line IL1, the third input line IL3, and the fifth input line IL5 may be electrically connected to a corresponding one selected from among the first data line DL1, the third data line DL3, and the fifth data line DL5 through a first contact hole CNT1. In the latter case, the first data line DL1, the third data line DL3, and the fifth data line DL5 may be positioned on an insulating layer covering the first input line IL1, the third input line IL3, and the fifth input line IL5. The first data line DL1, the third data line DL3, and the fifth data line DL5 may receive data signals from the first input line IL1, the third input line IL3, and the fifth input line IL5.

A shown in FIG. 2, the even ordered input lines, the second input line IL2, the fourth input line IL4, and the sixth input line IL6, may be electrically connected to the second data line DL2, the fourth data line DL4, and the sixth data line DL6, which are consecutively arranged adjacent to each other, through a first data transmission line DTL1, a second data transmission line DTL2, and a third data transmission line DTL3. For example, the second data line DL2, the fourth data line DL4, and the sixth data line DL6 may receive data signals from the second input line IL2, the fourth input line IL4, and the sixth input line IL6 through the first data transmission line DTL1, the second data transmission line DTL2, and the third data transmission line DTL3.

The first to third data transmission lines DTL1 to DTL3 may be arranged to pass through a part of the display area DA adjacent to the peripheral area PA, for example, to pass through the display area DA. The second input line IL2 is electrically connected to the second data line DL2 through the first data transmission line DTL1, the fourth input line IL4 is electrically connected to the fourth data line DL4 through the second data transmission line DTL2, and the sixth input line IL6 is electrically connected to the sixth data line DL6 through the third data transmission line DTL3.

One ends of the first data transmission line DTL1, the second data transmission line DTL2, and the third data transmission line DTL3 may be electrically connected to the second input line IL2, the fourth input line IL4, and the sixth input line IL6 through second contact holes CNT2, respectively, and the other ends of the first data transmission line DTL1, the second data transmission line DTL2, and the third data transmission line DTL3 may be connected to the second data line DL2, the fourth data line DL4, and the sixth data line DL6, respectively. The second contact hole CNT2 may be formed in the second peripheral area PA2, but one or more embodiments are not limited thereto. The second contact hole CNT2 may also be formed in the display area DA.

Through such a structure, the second input line IL2 may be to transmit a data signal to the second data line DL2, the fourth input line IL4 may be to transmit a data signal to the fourth data line DL4, and the sixth input line IL6 may be to transmit a data signal to the sixth data line DL6.

FIG. 3 is an equivalent circuit diagram of one circuit included in the display device of FIG. 1. Referring to FIG. 3, a pixel PX may include a pixel circuit PC and an OLED electrically connected thereto.

As shown in FIG. 3, the pixel circuit PC may include a plurality of thin-film transistors T1 to T8 and a storage capacitor Cst. The plurality of thin-film transistors T1 to T8 and the storage capacitor Cst may be connected to signal lines GWL, GCL, GIL, GBL, EL, and DL, a first initialization voltage line VIL, a second initialization voltage line VL, a driving voltage line PL, and a bias voltage line VBL. At least one selected from among these lines, for example, the driving voltage line PL, may be shared by adjacent pixels PX.

The plurality of thin-film transistors T1 to T8 may include a driving transistor T1, a switching transistor T2, a compensation transistor T3, a first initialization transistor T4, an operation control transistor T5, an emission control transistor T6, a bias transistor T7, and a second initialization transistor T8.

The OLED may include a pixel electrode and a counter electrode, the pixel electrode of the OLED may be connected to the driving transistor T1 through the emission control transistor T6 to receive a driving current, and the counter electrode may receive the common voltage ELVSS. The OLED may be to generate light with luminance corresponding to a driving current.

Some of the plurality of thin-film transistors T1 to T8 may be n-channel metal oxide silicon (NMOS) field effect transistors (NMOSFETs), and others may be p-channel metal oxide silicon (NMOS) field effect transistors (PMOSFETs). For example, among the plurality of thin-film transistors T1 to T8, the compensation transistor T3 and the first initialization transistor T4 may be NMOSFETs, and others may be PMOSFETs. In one or more embodiments, among the plurality of thin-film transistors T1 to T8, the compensation transistor T3, the first initialization transistor T4, and the second initialization transistor T8 may be NMOSFETs, and others may be PMOSFETs. In one or more embodiments, all of the thin-film transistors T1 to T8 may be NMOSFETs or PMOSFETs. The plurality of thin-film transistors T1 to T8 may include amorphous silicon or polysilicon. As suitable. a thin-film transistor that is an NMOSFET may include an oxide semiconductor. Hereinafter, for convenience, a case in which the compensation transistor T3 and the first initialization transistor T4 are NMOSFETs including an oxide semiconductor, and others are PMOSFETs will be described.

The signal lines GWL, GCL, RIL, GBL, EL, and DL may include a first scan line GWL transmitting a first scan signal GW, a second scan line GCL transmitting a second scan signal GC, a third scan line RIL transmitting an initialization scan signal RI to the first initialization transistor T4, a fourth scan line GBL transmitting a bias scan signal GB to the second initialization transistor T8, an emission control line EL transmitting an emission control signal EM to the operation control transistor T5 and the emission control transistor T6, and a data line DL intersecting (e.g., crossing) the first scan line GWL and transmitting a data signal DATA.

The driving voltage line PL may be to transmit a driving voltage ELVDD to the driving transistor T1, the first initialization voltage line VIL may be to transmit a first initialization voltage Vint for initializing the driving transistor T1, and a second initialization voltage line VL may be to transmit a second initialization voltage Vaint for initializing the pixel electrode of the OLED.

A driving gate electrode of the driving transistor T1 may be connected to the storage capacitor Cst through a second node N2, any one selected from among a source region and a drain region of the driving transistor T1 may be connected to the driving voltage line PL through a first node N1 and the operation control transistor T5, and the other of the source region and the drain region of the driving transistor T1 may be electrically connected to the pixel electrode of the OLED through a third node N3 and the emission control transistor T6. The driving transistor T1 may receive the data signal DATA to supply a driving current to the OLED according to a switching operation of the switching transistor T2. For example, in response to a voltage that is applied to the second node N2 and is changed according to the data signal DATA, the driving transistor T1 may control an amount of a current flowing to the OLED from the first node N1 electrically connected to the driving voltage line PL.

A switching gate electrode of the switching transistor T2 may be connected to the first scan line GWL transmitting the first scan signal GW, any one selected from among a source region and a drain region of the switching transistor T2 may be connected to the data line DL, and the other of the source region and the drain region of the switching transistor T2 may be connected to the driving transistor T1 through the first node N1 and connected to the driving voltage line PL through the operation control transistor T5. The switching transistor T2 may be to transmit the data signal DATA, which is received from the data line DL, to the first node N1 in response to a voltage applied to the first scan line GWL. For example, the switching transistor T2 may be turned on according to the first scan signal GW received through the first scan line GWL and may perform a switching operation of transmitting the data signal DATA transmitted to the data line DL to the driving transistor T1 through the first node N1.

A compensation gate electrode of the compensation transistor T3 may be connected to the second scan line GCL. Any one selected from among a source region and a drain region of the compensation transistor T3 may be connected to the pixel electrode of the OLED through the third node N3 and the emission control transistor T6. The other of the source region and the drain region of the compensation transistor T3 may be connected to a first capacitor electrode of the storage capacitor Cst and the driving gate electrode of the driving transistor T1 through the second node N2. The compensation transistor T3 may be turned on according to the second scan signal GC received through the second scan line GCL to diode-connect the driving transistor T1.

A first initialization gate electrode of the first initialization transistor T4 may be connected to the third scan line GIL. Any one selected from among a source region and a drain region of the first initialization transistor T4 may be connected to the first initialization voltage line VIL. The other of the source region and drain region of the first initialization transistor T4 may be connected to the first capacitor electrode of the storage capacitor Cst, the driving gate electrode of the driving transistor T1, and/or the like through the second node N2. The first initialization transistor T4 may apply the first initialization voltage Vint, which is received from the first initialization voltage line VIL, to the second node N2 in response to a voltage applied to a previous scan line GIL. For example, the first initialization transistor T4 may be turned on according to the initialization scan signal GI received through the third scan line GIL to perform an initialization operation of transmitting the first initialization voltage Vint to the driving gate electrode of the driving transistor T1 to initialize a voltage of the driving gate electrode of the driving transistor T1.

An operation control gate electrode of the operation control transistor T5 may be connected to the emission control line EL, one selected from among a source region and a drain region of the operation control transistor T5 may be connected to the driving voltage line PL, and the other one selected from among the source region and the drain region of the operation control transistor T5 may be connected to the driving transistor T1 and the switching transistor T2 through the first node N1.

An emission control gate electrode of the emission control transistor T6 may be connected to the emission control line EL, any one selected from among a source region and a drain region of the emission control transistor T6 may be connected to the driving transistor T1 and the compensation transistor T3 through the third node N3, and the other of the source region and the drain region of the emission control transistor T6 may be electrically connected to the pixel electrode of the OLED.

The operation control transistor T5 and the emission control transistor T6 are concurrently (e.g., simultaneously) turned on according to the emission control signal EM received through the emission control line EL, so that an electrical signal from the driving voltage ELVDD is transmitted to the OLED to allow a driving current to flow to the OLED.

The bias transistor T7 may be connected between the first node N1 and the bias voltage line VBL. The bias transistor T7 may be turned on according to the bias scan signal GB received through the fourth scan line GBL to apply a bias voltage VOBS to the first node N1, thereby presetting a voltage, which is suitable for a subsequent operation of the driving transistor T1, at the first node N1. In this respect, the fourth scan line GBL may be referred to as a bias gate line.

A second initialization gate electrode of the second initialization transistor T8 may be connected to the fourth scan line GBL, any one selected from among a source region and a drain region of the second initialization transistor T8 may be connected to the pixel electrode of the OLED, and the other of the source region and the drain region of the second initialization transistor T8 may be connected to the second initialization voltage line VL to receive the second initialization voltage Vaint. The second initialization transistor T8 is turned on according to the bias scan signal GB received through the fourth scan line GBL to initialize the pixel electrode of the OLED.

The storage capacitor Cst may include the first capacitor electrode and a second capacitor electrode. The first capacitor electrode of the storage capacitor Cst is connected to the driving gate electrode of the driving transistor T1 through the second node N2, and the second capacitor electrode of the storage capacitor Cst is connected to the driving voltage line PL. The storage capacitor Cst may store electric charges corresponding to a difference between a voltage of the driving gate electrode of the driving transistor T1 and the driving voltage ELVDD.

An operation of each pixel PX according to one or more embodiments is as follows.

During an initialization period, if (e.g., when) the initialization scan signal GI is supplied through the third scan line GIL, the first initialization transistor T4 is turned on in response to the initialization scan signal GI, and the driving transistor T1 is initialized by the first initialization voltage Vint supplied from the first initialization voltage line VIL. If (e.g., when) the bias scan signal GB is supplied through the fourth scan line GBL, the second initialization transistor T8 is turned on in response to the bias scan signal GB, and the pixel electrode of the OLED is initialized by the second initialization voltage Vaint supplied from the second initialization voltage line VL. In one or more embodiments, the bias transistor T7 is also turned on according to the bias scan signal GB to apply the bias voltage VOBS to the first node N1, thereby presetting a voltage, which is suitable for a subsequent operation of the driving transistor T1, at the first node N1.

During a data programming period, if (e.g., when) the first scan signal GW and the second scan signal GC are supplied through the first scan line GWL and the second scan line GCL, the switching transistor T2 and the compensation transistor T3 are turned on in response to the first scan signal GW and the second scan signal GC. In this case, the driving transistor T1 is diode-connected by the turned-on compensation transistor T3 and is forward biased. Then, a compensation voltage DATA+Vth (Vth has a negative value), which is obtained by subtracting a threshold voltage Vth of the driving transistor T1 from a voltage of the data signal DATA supplied from the data line DL, is applied to a driving gate electrode G1 of the driving transistor T1. The driving voltage ELVDD and the compensation voltage DATA+Vth are applied to opposite ends of the storage capacitor Cst, and electric charges corresponding to a voltage difference between the opposite ends are stored in the storage capacitor Cst.

During an emission period, the operation control transistor T5 and the emission control transistor T6 are turned on by the emission control signal EM supplied from the emission control line EL. A driving current is generated according to a voltage difference between a voltage of the driving gate electrode G1 of the driving transistor T1 and the driving voltage ELVDD, and the driving current is supplied to the OLED through the emission control transistor T6.

As described above, some of the plurality of thin-film transistors T1 to T8 may include an oxide semiconductor. For example, the compensation transistor T3 and the first initialization transistor T4 may include an oxide semiconductor.

Polysilicon may have relatively high reliability and thus may be controlled or selected to allow an intended current to flow accurately. Therefore, the driving transistor T1 that directly affects the brightness of a display device may be allowed to include a semiconductor layer including (e.g., made of) polysilicon with relatively high reliability, thereby implementing a high-resolution display device. In one or more embodiments, an oxide semiconductor has relatively high carrier mobility and relatively low leakage current, and thus a voltage drop is not significantly large even if (e.g., when) an operating time is long. For example, in the case of an oxide semiconductor, a color change of an image due to a voltage drop is not significantly large even during low-frequency driving, and thus low-frequency driving is possible. Accordingly, the compensation transistor T3 and the first initialization transistor T4 are allowed to include an oxide semiconductor, thereby preventing or reducing the occurrence of leakage current and concurrently (e.g., simultaneously) implementing a display device with reduced power consumption.

In one or more embodiments, the oxide semiconductor is sensitive to light, and thus an amount of a current and/or the like may change due to external light. Therefore, a metal layer may be positioned below (e.g., beneath or under) the oxide semiconductor to absorb or reflect external light. Accordingly, as shown in FIG. 3, in each of the compensation transistor T3 and the first initialization transistor T4 including the oxide semiconductor, gate electrodes may be positioned on and below (e.g., beneath or under) an oxide semiconductor layer, respectively. For example, if (e.g., when) viewed in a direction (z-axis direction) normal (e.g., perpendicular) to an upper surface of a substrate 100, the metal layer positioned below (e.g., beneath or under) the oxide semiconductor may overlap the oxide semiconductor.

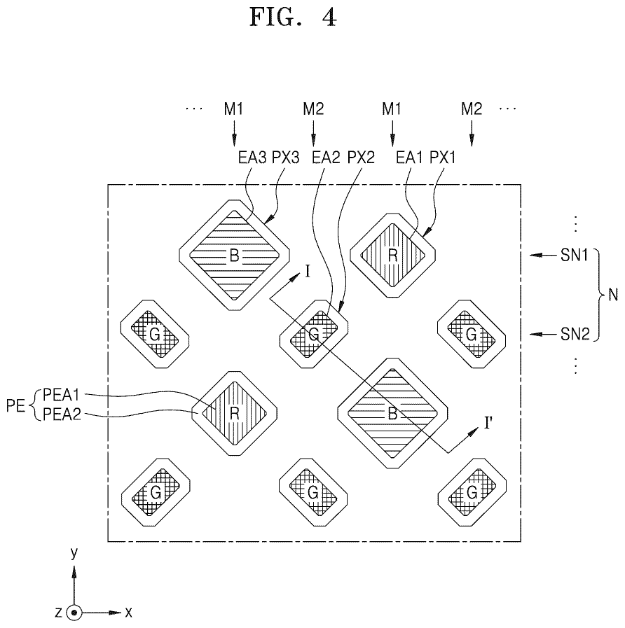

FIG. 4 is a schematic layout illustrating emission areas of a plurality of pixels included in the display device of FIG. 1.

Referring to FIG. 4, the plurality of pixels arranged in a display area DA may include a first pixel PX1, a second pixel PX2, and a third pixel PX3. The first pixel PX1, the second pixel PX2, and the third pixel PX3 may be repeatedly arranged in a certain pattern in the x-axis direction and the y-axis direction. The first pixel PX1, the second pixel PX2, and the third pixel PX3 may each include a pixel circuit and an OLED electrically connected to the pixel circuit. The OLED of each pixel may be arranged on an upper layer of the pixel circuit. The OLED may be arranged directly on the pixel circuit to overlap the pixel circuit or may be offset from the pixel circuit and arranged to partially overlap a pixel circuit of another pixel positioned in an adjacent row and/or an adjacent column.

FIG. 4 illustrates a pixel electrode PE and the emission area of each of the first pixel PX1, the second pixel PX2, and the third pixel PX3. The emission area is an area in which an emission layer of the OLED is arranged. The emission area may be defined by a pixel-defining layer having an opening corresponding to a central portion of the pixel electrode PE. Each pixel electrode PE may include a first area PEA1 corresponding to the emission area and a second area PEA2 around (e.g., surrounding) the first area PEA1. The first area PEA1 may correspond to the opening of the pixel-defining layer, and the second area PEA2 may be a portion covered by the pixel-defining layer.

In one or more embodiments, in a first column M1, a first emission area EA1 of the first pixel PX1 and a third emission area EA3 of the third pixel PX3 may be alternately arranged in the y-axis direction. In a second column M2, a second emission area EA2 of the second pixel PX2 may be repeatedly arranged in the y-axis direction. The first column M1 and the second column M2 are alternately positioned in the x-axis direction, and the arrangement of the first emission area EA1 of the first pixel PX1 and the third emission area EA3 of the third pixels PX3 of one first column M1 may be reverse to that of adjacent first column M1.

In one or more embodiments, in a first sub-row SN1 of each row N, the first emission area EA1 of the first pixel PX1 and the third emission area EA3 of the third pixel PX3 may be alternately arranged in the x-axis direction, and in a second sub-row SN2, the second emission area EA2 of the second pixel PX2 may be repeatedly arranged in the x-axis direction. For example, in each row N, the first emission area EA1 of the first pixel PX1, the second emission area EA2 of the second pixel PX2, the third emission area EA3 of the third pixel PX3, and the second emission area EA2 of the second pixel PX2 may be repeatedly arranged in a zigzag pattern.

In one or more embodiments, the first emission area EA1 of the first pixel PX1, the second emission area EA2 of the second pixel PX2, and the third emission area EA3 of the third pixel PX3 may have different areas. For example, the third emission area EA3 of the third pixel PX3 may have a larger area than the first emission area EA1 of the first pixel PX1. In one or more embodiments, the third emission area EA3 of the third pixel PX3 may have a larger area than the second emission area EA2 of the second pixel PX2. The first emission area EA1 of the first pixel PX1 may have a larger area than the second emission area EA2 of the second pixel PX2. In one or more embodiments, the third emission area EA3 of the third pixel PX3 may have the same area as the first emission area EA1 of the first pixel PX1. However, the present disclosure is not limited thereto. For example, one or more suitable modifications are possible in such a manner that the first emission area EA1 of the first pixel PX1 is larger than each of the second emission area EA2 of the second pixel PX2 and the third emission area EA3 of the third pixel PX3.

The first emission area EA1, the second emission area EA2, and the third emission area EA3 may have a polygonal shape such as a quadrangular shape, an octagonal shape, a circular shape, or an elliptical shape. The polygonal shape may be a shape with round corners (vertices).

The first pixel PX1 may be a green pixel G that emits green light, the second pixel PX2 may be a red pixel R that emits red light, and the third pixel PX3 may be a blue pixel B that emits blue light.

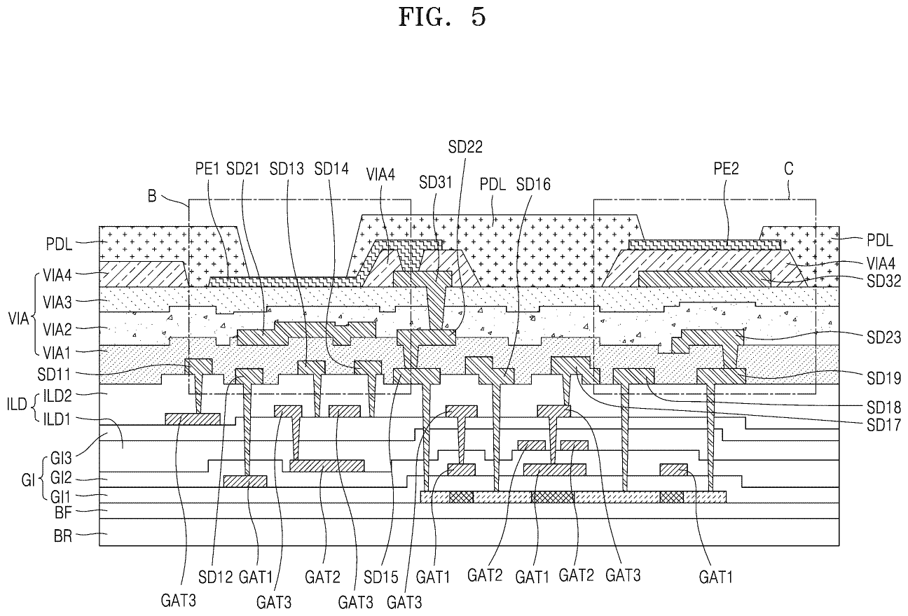

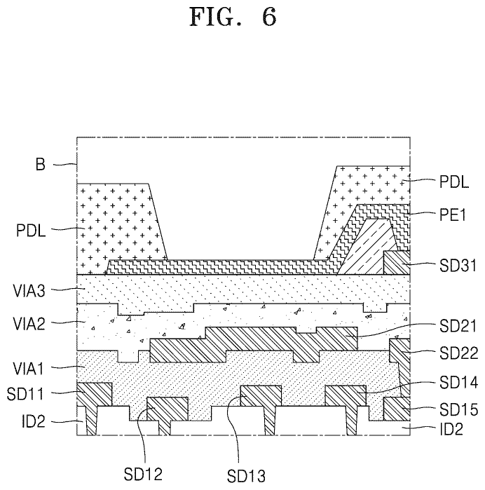

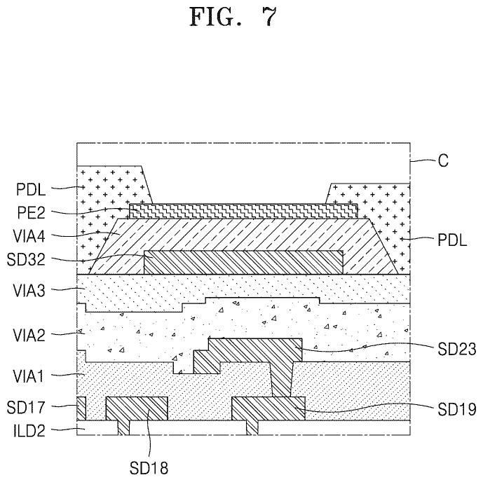

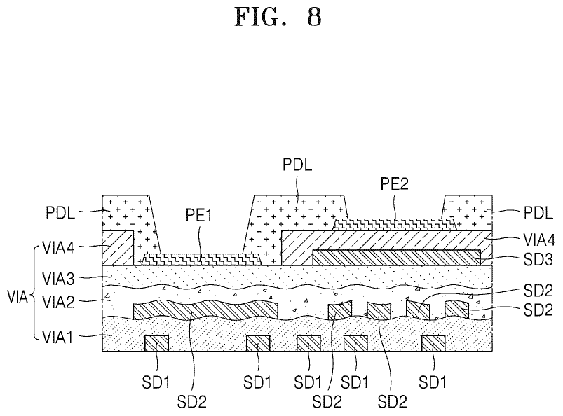

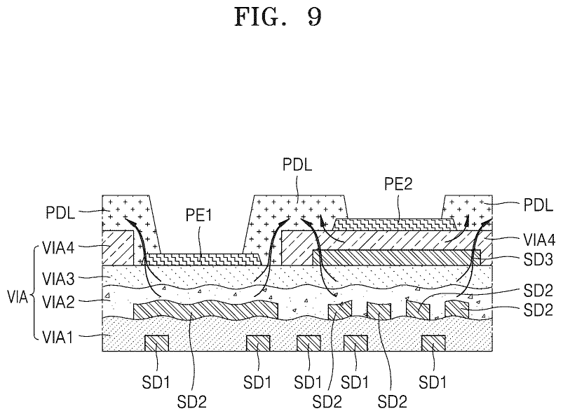

FIG. 5 is a cross-sectional view taken along the line I-I′ of FIG. 4. FIG. 6 is a schematic enlarged view illustrating part B of FIG. 5. FIG. 7 is a schematic enlarged view illustrating part C of FIG. 5. FIGS. 8 and 9 are schematic conceptual views illustrating the cross-sectional view shown in FIG. 5.

Referring to FIGS. 5 to 7, a display device according to one or more embodiments of the present disclosure may include a substrate 100, a barrier layer BR, a buffer layer BF, gate electrodes GAT1, GAT2, and GAT3, a gate insulating layer GI, an interlayer insulating layer ILD, an insulating layer VIA, and a pixel-defining layer PDL.

The barrier layer BR may be arranged on the substrate 100 to protect organic materials, inorganic materials, and other materials forming the display device from being damaged by an external environment.

The substrate 100 may include (e.g., be made of) one or more suitable materials such as glass, metal, and/or plastic. According to one or more embodiments, the substrate 100 may be a flexible substrate and may include, for example, a polymer resin such as polyethersulfone (PES), polyarylate (PAR), polyetherimide (PEI), polyethyelenennapthalate (PEN), polyethyeleneterepthalate (PET), polyphenylenesulfide (PPS), polyallylate, polyimide (PI), polycarbonate (PC), or cellulose acetate propionate (CAP).

The buffer layer BF may be formed on the substrate 100 to prevent or reduce impurities from penetrating into a semiconductor layer of a thin-film transistor.

The buffer layer BF may include an inorganic insulating material such as silicon nitride or silicon oxide and may be a single layer or a multi-layer.

A thin-film transistor, a capacitor, and an OLED electrically connected to the thin-film transistor may be arranged on the substrate 100. The OLED being electrically connected to the thin-film transistor may be understood as a pixel electrode PE being electrically connected to the thin-film transistor.

The plurality of gate electrodes GAT1, GAT2, and GAT3 and a plurality of gate insulating layers GI may be arranged on the buffer layer BF.

In one or more embodiments, a first gate insulating layer GI1 may be arranged on the buffer layer BF. At least one first gate electrode GAT1 may be arranged on the first gate insulating layer GI1. A second gate insulating layer GI2 may be arranged on the first gate electrode GAT1. At least one second gate electrode GAT2 may be arranged on the second gate insulating layer GI2. A third gate insulating layer GI3 may be arranged on the second gate electrode GAT2. At least one third gate electrode GAT3 may be arranged on the third gate insulating layer GI3.

Although the drawing illustrates that the first gate electrode GAT1, the second gate electrode GAT2, and the third gate electrode GAT3 are provided as the gate electrodes GAT1, GAT2, and GAT3, and the first gate insulating layer GI1, the second gate insulating layer GI2, and the third gate insulating layer GI3 are provided as the gate insulating layers GI, one or more embodiments are not limited thereto, and more gate electrodes GAT1, GAT2, GAT3 and gate insulating layers GI1, GI2, GI3 may be provided as needed.

In consideration of adhesion to adjacent layers, surface flatness of stacked layers, and processability, for example, the gate electrodes GAT1, GAT2, and GAT3 may be formed as a single layer or a multi-layer including (e.g., made of) at least one material selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), andcopper (Cu).

The gate insulating layer GI may include an inorganic insulating material such as silicon oxide, silicon nitride, silicon oxynitride, aluminum oxide, titanium oxide, tantalum oxide, or hafnium oxide. The gate insulating layer GI may be a single layer or a multi-layer including the material described above (e.g., the inorganic insulating material).

The interlayer insulating layer ILD may be arranged adjacent to the gate insulating layer GI.

In one or more embodiments, a first interlayer insulating layer ILD1 may be arranged between the second gate insulating layer GI2 and the third gate insulating layer GI3. A second interlayer insulating layer ILD2 may be arranged on the third gate insulating layer GI3.

The interlayer insulating layer ILD may include inorganic materials such as silicon oxide, silicon nitride, and/or silicon oxynitride.

A plurality of connection electrodes SD11, SD12, SD13, SD14, SD15, SD16, SD17, SD18, SD19, SD21, SD22, SD23, SD31, and SD32 and a plurality of insulating layers VIA may be further arranged on the interlayer insulating layer ILD.

The connection electrodes SD11, SD12, SD13, SD14, SD15, SD16, SD17, SD18, SD19, SD21, SD22, SD23, SD31, and SD32 may include source electrodes and drain electrodes. The connection electrodes SD11, SD12, SD13, SD14, SD15, SD16, SD17, SD18, SD19, SD21, SD22, SD23, SD31, and SD32 may be electrically connected to the semiconductor layer through contact holes formed in the gate insulating layer GI, the interlayer insulating layer ILD, and the insulating layer VIA.

The connection electrodes SD11, SD12, SD13, SD14, SD15, SD16, SD17, SD18, SD19, SD21, SD22, SD23, SD31, and SD32 may be formed as a single layer or multi-layer including (e.g., made of) at least one material selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The insulating layer VIA arranged on the connection electrodes SD11, SD12, SD13, SD14, SD15, SD16, SD17, SD18, SD19, SD21, SD22, SD23, SD31, and SD32 may be an organic insulating layer. For example, the insulating layer VIA may include at least one selected from among organic insulating materials such as a general-purpose polymer such as polymethylmethacrylate (PMMA) or polystylene (PS), a polymer derivative having a phenol group, an acrylic polymer, an imide-based polymer, an aryl ether-based polymer, an amide-based polymer, a fluorine-based polymer, a p-xylene-based polymer, a vinyl alcohol-based polymer, and a blend thereof. For example, the insulating layer VIA may include PI.

The connection electrodes SD11, SD12, SD13, SD14, SD15, SD16, SD17, SD18, SD19, SD21, SD22, SD23, SD31, and SD32 may be arranged on the interlayer insulating layer ILD.

For example, a plurality of first connection electrodes SD11, SD12, SD13, SD14, SD15, SD16, SD17, SD18, and SD19 may be arranged on the second interlayer insulating layer ILD2. At least some of the first connection electrodes SD11, SD12, SD13, SD14, SD15, SD16, SD17, SD18, and SD19 may be electrically connected to the third gate electrode GAT3 through contact holes formed in the second interlayer insulating layer ILD2.

A first insulating layer VIA1 may be arranged on the first connection electrodes SD11, SD12, SD13, SD14, SD15, SD16, SD17, SD18, and SD19. The first insulating layer VIA1 may be arranged in a display area DA as well as a peripheral area PA on the substrate 100.

A plurality of second connection electrodes SD21, SD22, and SD23 may be arranged on the first insulating layer VIA1. At least some of the second connection electrodes SD21, SD22, and SD23 may be electrically connected to the first connection electrodes SD11, SD12, SD13, SD14, SD15, SD16, SD17, SD18, and SD19 through contact holes formed in the first insulating layer VIA1.

A second insulating layer VIA2 may be arranged on the second connection electrodes SD21, SD22, and SD23.

A third insulating layer VIA3 may be arranged on the second insulating layer VIA2.

In one or more embodiments, the third insulating layer VIA3 may be a planarizing layer. For example, the third insulating layer VIA3 may be formed on the second insulating layer VIA2 and then planarized. The third insulating layer VIA3 may be arranged on the second insulating layer VIA2 to be in contact with the second insulating layer VIA2. From different standpoints, it may be described that the third insulating layer VIA3 is a layer additionally formed to form a planarizing layer on the second insulating layer VIA2 after the second insulating layer VIA2 is formed.

The third insulating layer VIA3 may be formed as a planarizing layer, so that the surface planarization may be achieved, and the electrical interference between the third insulating layer VIA3 and an adjacent layer may be reduced, and if (e.g., when) the pixel electrode PE is arranged on the third insulating layer VIA3, the adhesion to the pixel electrode PE may be improved.

Third connection electrodes SD31 and SD32 may be arranged on the third insulating layer VIA3. For example, the third connection electrodes SD31 and SD32 may be arranged on the third insulating layer VIA3. Here, the third connection electrodes SD31 and SD32 may be electrodes to which a driving voltage ELVDD is applied.

A fourth insulating layer VIA4 may be arranged on the third connection electrodes SD31 and SD32. For example, the fourth insulating layer VIA4 may be arranged on the third insulating layer VIA3 to cover the third connection electrodes SD31 and SD32. In one or more embodiments, the fourth insulating layer VIA4 is arranged on the third insulating layer VIA3, so that the fourth insulating layer VIA4 is further formed on the third insulating layer VIA3 which is already planarized.

In one or more embodiments, the fourth insulating layer VIA4 may be a planarizing layer.

The fourth insulating layer VIA4 may be formed as a planarizing layer, so that the surface planarization may be achieved, the electrical interference between the fourth insulating layer VIA4 and an adjacent layer may be reduced, and if (e.g., when) the pixel electrode PE is arranged on the fourth insulating layer VIA4, the adhesion to the pixel electrode PE may be improved.

A display element, for example, the OLED, may be arranged above the third insulating layer VIA3. The OLED may include the pixel electrode PE. In one or more embodiments, the OLED may further include an intermediate layer and a counter electrode.

The pixel electrode PE may be arranged above the third insulating layer VIA3 and connected to the thin-film transistor through the connection electrode.

The pixel electrode PE may include a conductive oxide such as indium tin oxide (e.g., ITO), indium zinc oxide (e.g., IZO), zinc oxide (e.g., ZnO), indium oxide (e.g., In₂O₃), indium gallium oxide (e.g., IGO), or aluminum zinc oxide (e.g., AZO). In one or more embodiments, the pixel electrode PE may include a reflective film including silver (Ag), magnesium (Mg), aluminum (Al), platinum (Pt), palladium (Pd), gold (Au), nickel (Ni), neodymium (Nd), iridium (Ir), chromium (Cr), and/or a compound thereof. In one or more embodiments, the pixel electrode PE may further include a film including (e.g., made of) ITO, IZO, ZnO, and/or In₂O₃ on/below (e.g., beneath or under) the above-described reflective film.

The intermediate layer may include an emission layer including a polymer and/or a low-molecular-weight organic material that emits light with a certain color.

The counter electrode may be arranged to face the pixel electrode PE with the intermediate layer arranged between the counter electrode and the pixel electrode PE. The counter electrode may include (e.g., be made of) a conductive material with a low work function. For example, the counter electrode may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or an alloy thereof. In one or more embodiments, the counter electrode may further include a layer including (e.g., made of) ITO, IZO, ZnO and/or In₂O₃ on the (semi)transparent layer including the above-described material.

The counter electrode may be arranged on the intermediate layer and the pixel-defining layer PDL. The counter electrode may be integrally formed in a plurality of OLEDs in the display area DA and thus may face a plurality of pixel electrodes PE.

The pixel-defining layer PDL may be further arranged on the third insulating layer VIA3. For example, the fourth insulating layers VIA4 may be formed to be spaced and/or apart (e.g., spaced apart or separated) from each other to cover a partial area of the third insulating layer VIA3. In this case, the pixel-defining layer PDL may be arranged on the fourth insulating layer VIA4. From different standpoints, it may be described that the pixel-defining layer PDL is arranged on the third insulating layer VIA3 and the fourth insulating layer VIA4 to cover at least a portion of the third insulating layer VIA3 and at least a portion of the fourth insulating layer VIA4.

The pixel-defining layer PDL may be arranged to cover an edge of the pixel electrode PE. Thus, the pixel-defining layer PDL may include an opening that allows a portion of the pixel electrode PE to be exposed. For example, a plurality of openings may be formed in the pixel-defining layer PDL, e.g., at least two openings may be defined in the pixel-defining layer PDL. Each pixel may be arranged in each opening. Therefore, each opening may correspond to an emission area EA. From different standpoints, it may be described that a plurality of emission areas EA are defined by respective openings.

The pixel-defining layer PDL may prevent or reduce arcs and/or the like from occurring at the edge of the pixel electrode PE by increasing a distance between the edge of the pixel electrode PE and the counter electrode. The pixel-defining layer PDL may include (e.g., be made of) an organic material such as PI or hexamethyldisiloxane (HMDSO).

In one or more embodiments, the pixel-defining layer PDL may be a black pixel-defining layer (e.g., black-PDL (BPDL)).

For example, the pixel-defining layer PDL may be formed by including a light-absorbing material or by including a black pigment or a black dye. The pixel-defining layer PDL formed by including the black pigment or the black dye may implement a BPDL. If (e.g., when) the pixel-defining layer PDL is formed, carbon black and/or the like may be utilized as a black pigment or black dye, but one or more embodiments are not limited thereto.

The pixel-defining layer PDL may be implemented as a BPDL to absorb at least a portion of light incident on the pixel-defining layer PDL. Here, the light may be external light or reflected light reflected from the counter electrode, but the present disclosure is not limited thereto.

A thin-film encapsulation layer as an encapsulation member may be further arranged on the OLED. The thin-film encapsulation layer serves to protect the OLED from external moisture and/or oxygen. The thin-film encapsulation layer may have a multilayer structure. The thin-film encapsulation layer may include a plurality of inorganic layers and a plurality of organic layers. By forming the thin-film encapsulation layer to have the multilayer structure, even if (e.g., when) a crack occurs in the thin-film encapsulation layer, the crack may be prevented or reduced from propagating between each inorganic layer and each organic layer. Thus, it is possible to prevent, reduce, or minimize the formation of a path through which external moisture and/or oxygen penetrates into the display area DA. In one or more embodiments, the number of organic layers, the number of inorganic layers, and a stacking order thereof may be changed.

In one or more embodiments, during a process of forming the thin-film encapsulation layer, structuresbelow (e.g., beneath or under) the thin-film encapsulation layer may be damaged. Therefore, to prevent or reduce damage to the structures below (e.g., beneath or under) the thin-film encapsulation layer during the process of forming the thin-film encapsulation layer, at least one capping layer and/or protective layer may be interposed between the counter electrode and the thin-film encapsulation layer. The protective layer may include an inorganic material.

In one or more embodiments, the plurality of emission areas EA may have different stacked structures. Hereinafter, a stacked structure of the emission area EA according to one or more embodiments of the present disclosure will be described with reference to FIGS. 6 and 7.

FIG. 6 is a schematic enlarged view illustrating part B of FIG. 5 and illustrates a first emission area EA1 in which a first pixel electrode PE1 is arranged.

Referring to FIGS. 5 and 6, the first pixel electrode PE1 may be arranged, such that a central portion of the first pixel electrode PE1 is exposed by the pixel-defining layer PDL. The pixel-defining layer PDL may be formed to cover an edge of the first pixel electrode PE1.

In one or more embodiments, the first pixel electrode PE1 may be arranged above the third insulating layer VIA3, such that at least a portion of the first pixel electrode PE1 is in contact with the third insulating layer VIA3. For example, an additional layer may not be arranged between the third insulating layer VIA3 and the first pixel electrode PE1 (e.g., an area of the first pixel electrode PE1 exposed by the opening is in direct contact with the third insulating layer VIA3) to keep at least a portion of the first pixel electrode PE1 in contact with the third insulating layer VIA3.

The first pixel electrode PE1 may be electrically connected to the third connection electrode SD31 arranged below (e.g., beneath or under) the pixel-defining layer PDL. The third connection electrode SD31 may be positioned at a position that does not overlap the opening of the pixel-defining layer PDL. The fourth insulating layer VIA4 may be arranged on the third connection electrode SD31 not to overlap the opening of the pixel-defining layer PDL. The central portion of the first pixel electrode PE1 may be exposed to the outside by the opening, and one unexposed area thereof may extend to the fourth insulating layer VIA4 and then may be electrically connected to the third connection electrode SD31 through a contact hole formed in the fourth insulating layer VIA4.

FIG. 7 is a schematic enlarged view illustrating part C of FIG. 5 and illustrates a second emission area EA2 in which a second pixel electrode PE2 is arranged.

Referring to FIGS. 5 and 7, the second pixel electrode PE2 may be positioned such that a central portion thereof is exposed by the pixel-defining layer PDL. The pixel-defining layer PDL may be formed to cover an edge of the second pixel electrode PE2.

In one or more embodiments, the second pixel electrode PE2 may be formed on the third insulating layer VIA3 and may be arranged not to be in contact with the third insulating layer VIA3. For example, an additional layer may be arranged between the third insulating layer VIA3 and an area of the second pixel electrode PE2 exposed by the opening.

The third connection electrode SD32 may be arranged on the third insulating layer VIA3. The third connection electrode SD32 may be arranged at a position that overlaps an opening in which the second pixel electrode PE2 is arranged. The fourth insulating layer VIA4 may be arranged on the third insulating layer VIA3 to cover the third connection electrode SD32. For example, the fourth insulating layer VIA4 may be arranged to cover the third connection electrode SD32 at a position that overlaps the opening of the pixel-defining layer PDL.

In one or more embodiments, a thickness of the insulating layer VIA positioned at a position overlapping a portion at which the first pixel electrode PE1 is exposed may be different from a thickness of the insulating layer VIA positioned at a position overlapping a portion at which the second pixel electrode PE2 is exposed. In one or more embodiments, the thickness of the insulating layer VIA positioned at the position overlapping the portion at which the first pixel electrode PE1 is exposed may be less than the thickness of the insulating layer VIA positioned at the position overlapping the portion at which the second pixel electrode PE2 is exposed.

As described above, the first insulating layer VIA1, the second insulating layer VIA2, and the third insulating layer VIA3 may be arranged at the position overlapping the portion at which the first pixel electrode PE1 is exposed. In one or more embodiments, the first insulating layer VIA1, the second insulating layer VIA2, the third insulating layer VIA3, and the fourth insulating layer VIA4 may be arranged at the position overlapping the portion at which the second pixel electrode PE2 is exposed. Therefore, the thickness of the insulating layer VIA positioned at the position overlapping the portion at which the first pixel electrode PE1 is exposed is less than the thickness of the insulating layer VIA positioned at the position overlapping the portion at which the second pixel electrode PE2 is exposed.

In one or more embodiments, a distance from an uppermost portion of the pixel-defining layer PDL to the portion at which the first pixel electrode PE1 is exposed may be different from a distance from the uppermost portion of the pixel-defining layer PDL to the portion at which the second pixel electrode PE2 is exposed. In one or more embodiments, the distance from the uppermost portion of the pixel-defining layer PDL to the portion at which the first pixel electrode PE1 is exposed may be longer than the distance from the uppermost portion of the pixel-defining layer PDL to the portion at which the second pixel electrode PE2 is exposed.

As described above, the fourth insulating layer VIA4 and the third connection electrode SD32 may be arranged between the second pixel electrode PE2 and the third insulating layer VIA3, and thus the distance from the uppermost portion of the pixel-defining layer PDL to the portion at which the first pixel electrode PE1 is exposed is longer than the distance from the uppermost portion of the pixel-defining layer PDL to the portion at which the second pixel electrode PE2 is exposed.

In one or more embodiments, an emission layer that emits green light may be arranged on the first pixel electrode PE1. In one or more embodiments, an emission layer that emits red and/or blue light may be arranged on the second pixel electrode PE2. For example, a pixel in which the first pixel electrode PE1 is arranged may be a green pixel G that emits green light, and a pixel in which the second pixel electrode PE2 is arranged may be a red pixel R that emits red light or a blue pixel B that emits blue light.

Green has higher luminance than red and blue and thus has high visibility even if (e.g., when) color interference or a coupling effect occurs. In one or more embodiments, green which has high luminance has relatively strong luminescence characteristics so that, even if (e.g., when) a coupling effect occurs, color distortion or interference is not well displayed.

Accordingly, as described above, the pixel in which the first pixel electrode PE1 is arranged may be provided as the green pixel G, and the pixel in which the second pixel electrode PE2 is arranged may be provided as the red pixel R or the blue pixel B so that, while the flatness of the third insulating layer VIA3 may be secured, the third connection electrodes SD31 and SD32 and the fourth insulating layer VIA4 may be formed. Even in this case, a color distortion phenomenon due to coupling or the degradation of visibility due to interference may be reduced.

Hereinafter, the effects of a display device according to one or more embodiments of the present disclosure will be described in more detail.

Here, FIG. 8 is a conceptual schematic view of FIG. 5. FIG. 9 is a view for describing outgassing occurring in an organic film in FIG. 8.

Referring again to FIGS. 5 and 8, a display device according to one or more embodiments of the present disclosure may include second connection electrodes SD21, SD22, and SD23 arranged on a first insulating layer VIA1. In one or more embodiments, a second insulating layer VIA2 may be arranged on the second connection electrodes SD21, SD22, and SD23. In one or more embodiments, a third insulating layer VIA3 which is a planarizing layer may be arranged on the second insulating layer VIA2. In one or more embodiments, third connection electrodes SD31 and SD32 may be arranged on the third insulating layer VIA3. In one or more embodiments, a fourth insulating layer VIA4 may be arranged on the third connection electrodes SD31 and SD32. Thus, a data load and a scan load between the second connection electrodes SD21, SD22, and SD23 and the third connection electrodes SD31 and SD32 may be reduced. In one or more embodiments, the second connection electrodes SD21, SD22, or SD23 may be a portion at which a data line for transmitting or receiving a data signal is arranged, and the third connection electrode SD31 or SD32 may be a portion to which a driving voltage ELVDD is applied. Accordingly, the second insulating layer VIA2 and the planarized third insulating layer VIA3 may be arranged between the second connection electrodes SD21, SD22, and SD23 and the third connection electrodes SD31 and SD32 to secure a gap between the second connection electrodes SD21, SD22, and SD23 and the third connection electrodes SD31 and SD32, thereby reducing a data load and a scan load.

In one or more embodiments, if (e.g., when) the second insulating layer VIA2 is arranged on the second connection electrodes SD21, SD22, and SD23, the third connection electrodes SD31 and SD32 are arranged on the second insulating layer VIA2, and the third insulating layer VIA3 is arranged on the third connection electrodes SD31 and SD32, a gap between the second connection electrodes SD21, SD22, and SD23 and the third connection electrodes SD31 and SD32 is not secured, resulting in a problem in that a data load and a scan load are increased.

In one or more embodiments, according to one or more embodiments of the present disclosure, the third insulating layer VIA3 which is a planarizing layer may be formed below (e.g., beneath or under) a pixel electrode PE, thereby improving diffused reflection characteristics of a connection electrode. In one or more embodiments, as shown in FIG. 8 and/or the like, a plurality of first connection electrodes SD11, SD12, SD13, SD14, SD15, SD16, SD17, SD18, and SD19 and the second connection electrodes SD21, SD22, and SD23 may be arranged below (e.g., beneath or under) the pixel electrode PE. Accordingly, due to the first connection electrodes SD11, SD12, SD13, SD14, SD15, SD16, SD17, SD18, and SD19 and the second connection electrodes SD21, SD22, and SD23, a curved surface is formed below (e.g., beneath or under) the pixel electrode PE. In this case, diffused reflection may occur below (e.g., beneath or under) the pixel electrode PE, which may reduce the clarity and visibility of light emitted from a pixel. According to one or more embodiments of the present disclosure, the third insulating layer VIA3 which is a planarizing layer may be additionally formed on the second insulating layer VIA2, thereby obtaining effects in which diffused reflection characteristics due to flexures of the first connection electrodes SD11, SD12, SD13, SD14, SD15, SD16, SD17, SD18, and SD19 and the second connection electrodes SD21, SD22, and SD23 may be uniformly (e.g., substantially uniformly) distributed, the clarity and visibility of light may be improved, and also the visibility may be uniformly (e.g., substantially uniformly) maintained according to an observation angle.

Referring again to FIGS. 5 and 9, the display device according to one or more embodiments of the present disclosure may have an effect of reducing outgassing occurring in the organic film.

Here, outgassing refers to a phenomenon in which organic substances and/or other substances are discharged from organic materials in the form of gas. A degree of occurrence of outgassing may be determined by a thickness of the organic film, and according to the present disclosure, the thickness of the utilized organic film may be reduced, thereby obtaining an effect of improving outgassing.

In one or more embodiments, the display device according to one or more embodiments of the present disclosure may have a configuration in which the third insulating layer VIA3 which is a planarizing layer is formed on the second insulating layer VIA2, and a first pixel electrode PE1 is arranged above the third insulating layer VIA3, or the third connection electrodes SD31, and SD32 and the fourth insulating layer VIA4 are formed on the third insulating layer VIA3 to then arrange a second pixel electrode PE2. Accordingly, as compared to a case in which a separate planarizing layer is additionally formed on the third insulating layer VIA3 after the third insulating layer VIA3 is formed on the third connection electrodes SD31 and SD32, the thickness of the organic layer may be reduced, thereby obtaining an effect of reducing outgassing.

Hereinafter, a method for manufacturing a display device according to one or more embodiments of the present disclosure will be described.

Hereinafter, for the convenience of description, the same contents as those described above or the contents suitably applicable by a person of ordinary skill in the art to which the present disclosure belongs will not be provided or briefly described.

The method for manufacturing a display device according to one or more embodiments of the present disclosure may include preparing a substrate 100, forming first connection electrodes SD11, SD12, SD13, SD14, SD15, SD16, SD17, SD18, and SD19 on the substrate 100, forming a first insulating layer VIA1 on the first connection electrodes SD11, SD12, SD13, SD14, SD15, SD16, SD17, SD18, and SD19, forming second connection electrodes SD21, SD22, and SD23 on the first insulating layer VIA1, forming a third insulating layer VIA3 on the second connection electrodes SD21, SD22, and SD23, and forming a third connection electrodes SD31 and SD32 on the third insulating layer VIA3.

The preparing of the substrate 100 may include preparing the substrate 100 including a glass material and/or a polymer resin.

The forming of the first connection electrodes SD11, SD12, SD13, SD14, SD15, SD16, SD17, SD18, and SD19 on the substrate 100, the forming of the first insulating layer VIA1, the forming of the second connection electrodes SD21, SD22, and SD23, the forming of the second insulating layer VIA2, the forming of the third insulating layer VIA3, and the forming of the third connection electrodes SD31 and SD3 may be performed through a photolithography process utilizing a photomask.

In one or more embodiments, the forming of the third insulating layer VIA3 may include planarizing the third insulating layer VIA3. For example, according to one or more embodiments of the present disclosure, the method may further include arranging the third insulating layer VIA3, which is a planarizing layer, on the second insulating layer VIA2.

For example, after the third connection electrodes SD31 and SD32 are formed, forming a fourth insulating layer VIA4 on the third connection electrodes SD31 and SD32 may be further performed. The fourth insulating layers VIA4 may be formed to be spaced and/or apart (e.g., spaced apart or separated) from each other to cover a partial area of the third insulating layer VIA3. In one or more embodiments, the fourth insulating layer VIA4 may be arranged to cover the third connection electrodes SD31 and SD32.

After the fourth insulating layer VIA4 is formed, forming a pixel electrode PE may be further performed.

The forming of the pixel electrode PE may include forming a first pixel electrode PE1 and a second pixel electrode PE2 on the fourth insulating layer VIA4. After the pixel electrode PE is formed, forming an emission layer and a counter electrode on the pixel electrode PE may be further performed.

After the pixel electrode PE is formed, forming a pixel-defining layer PDL may be further performed. The forming of the pixel-defining layer PDL may include forming the pixel-defining layer PDL to have openings that expose central portions of the first pixel electrode PE1 and the second pixel electrode PE2. The central portion of each of the first pixel electrode PE1 and the second pixel electrode PE2 may be arranged to be exposed in the opening.

In this case, a distance from an uppermost portion of the pixel-defining layer PDL to a portion at which the first pixel electrode PE1 is exposed may be different from a distance from the uppermost portion of the pixel-defining layer PDL to a portion at which the second pixel electrode PE2 is exposed.

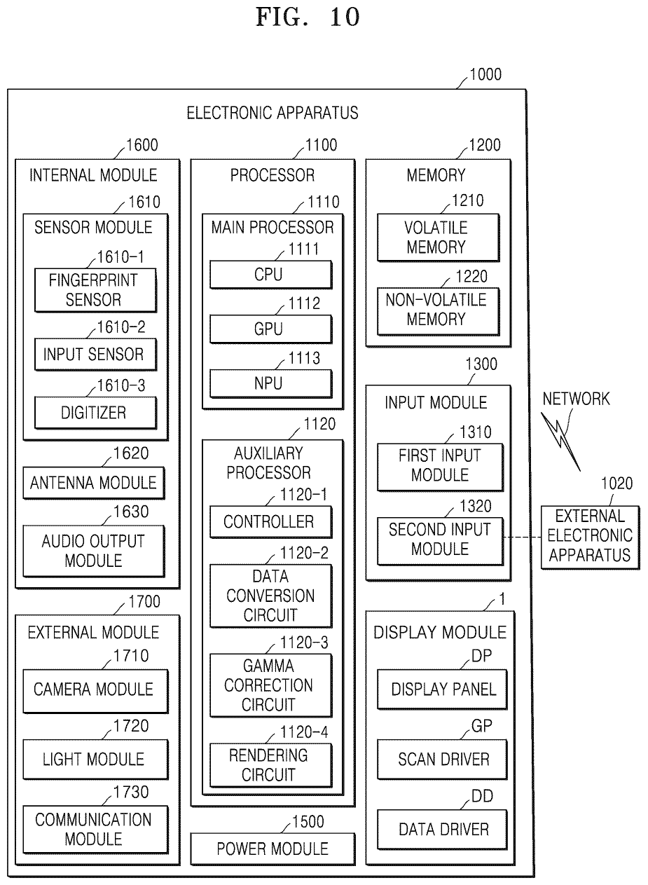

FIG. 10 is a block diagram of an electronic apparatus 1000 according to one or more embodiments of the present disclosure.

Referring to FIG. 10, the electronic apparatus 1000 outputs one or more suitable types (kinds) of information through a display device 1 in an operating system. In this case, the display device 1 may be the display device shown and described with reference to FIGS. 1 to 9. If (e.g., when) a processor 1100 executes an application stored in a memory 1200, the display device 1 provides application information to a user through a display panel DP.

The processor 1100 acquires an external input through an input module 1300 (e.g., an input device) or a sensor module 1610 (e.g., a sensor) and executes an application corresponding to the external input. For example, if (e.g., when) a user selects a camera icon displayed on the display panel DP, the processor 1100 acquires a user input through an input sensor 1610-2 and activates a camera module 1710 (e.g., a camera). The processor 1100 transmits image data, which corresponds to a captured image acquired through the camera module 1710, to the display device 1. The display device 1 may display an image corresponding to a captured image through the display panel DP.

In one or more embodiments, if (e.g., when) personal information authentication is performed in the display device 1, a fingerprint sensor 1610-1 acquires input fingerprint information as input data. The processor 1100 compares input data acquired through the fingerprint sensor 1610-1 with authentication data stored in the memory 1200 and executes an application according to a comparison result. The display device 1 may display information, which is executed according to a logic of an application, through the display panel DP.

In one or more embodiments, if (e.g., when) a music streaming icon displayed on the display device 1 is selected, the processor 1100 acquires a user input through the input sensor 1610-2 and activates a music streaming application stored in the memory 1200. If (e.g., when) a music execution instruction is input through the music streaming application, the processor 1100 activates an audio output module 1630 (e.g., an audio output device) to provide a user with audio information corresponding to the music execution instruction.

The operation of the electronic apparatus 1000 has been briefly described above. Hereinafter, the configuration of the electronic apparatus 1000 will be described in more detail. Some of components of the electronic apparatus 1000, which will be described in more detail, may be integrated and provided as one component, and one component may be provided by being separated into two or more components.

Referring to FIG. 10, the electronic apparatus 1000 may communicate with an external electronic apparatus 1020 through a network (for example, a short-range wireless communication network or a long-range wireless communication network). According to one or more embodiments, the electronic apparatus 1000 may include the processor 1100, the memory 1200, the input module 1300, the display device 1, a power module 1500 (e.g., a power supply), an embedded module 1600 (e.g., an embedded device, such as an embedded system module (ESM)), and an external module 1700 (e.g., an external device, such as an external sound device). According to one or more embodiments, in the electronic apparatus 1000, at least one selected from among the above-described components may not be provided, or one or more other components may be added. In one or more embodiments, among the above-described components, some components (for example, the sensor module 1610, an antenna module 1620 (e.g., an antenna), or the audio output module 1630) may be integrated into another component (for example, the display device 1).

The processor 1100 may execute software, may control at least one (for example, a hardware or software component) of other components of the electronic apparatus 1000, which are connected to the processor 1100, and may perform one or more suitable data processing or calculations. According to one or more embodiments, as at least part of the data processing or calculations, the processor 1100 may store instructions or data received from another component (for example, the input module 1300, the sensor module 1610, or a communication module 1730 (e.g., a communication device)) in a volatile memory 1210, may process the instructions or data stored in the volatile memory 1210, and may store resulting data in a non-volatile memory 1220.

The processor 1100 may include a main processor 1110 and an auxiliary processor 1120. The main processor 1110 may include at least one of a central processing unit (CPU) 1111 or an application processor (AP). The main processor 1110 may further include at least one selected from among a graphic processing unit (GPU) 1112, a communication processor (CP), and an image signal processor (ISP). The main processor 1110 may further include a neural processing unit (NPU) 1113. The NPU 1113 may be a processor specialized in processing an artificial intelligence model, and the artificial intelligence model may be generated through machine learning. The artificial intelligence model may include a plurality of artificial neural network layers. The artificial neural network may be one selected from among a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and/or a (e.g., any suitable) combination of two or more thereof, but is not limited to the examples described above. The artificial intelligence model may additionally or alternatively include a software structure in addition to a hardware structure. At least two of the above-described processing units and/or processors may be implemented as one integrated component (for example, a single chip), or the above-described processing units and processors may be respectively implemented as independent components (for example, a plurality of chips).

The auxiliary processor 1120 may include a controller 1120-1. The controller 1120-1 may include an interface conversion circuit and a timing control circuit. The controller 1120-1 receives an image signal from the main processor 1110, converts a data format of the image signal according to a specification for interfacing with the display device 1, and outputs the image data. The controller 1120-1 may output one or more suitable control signals suitable for driving the display device 1.

The auxiliary processor 1120 may further include the controller 1120-1, a data conversion circuit 1120-2, a gamma correction circuit 1120-3, a rendering circuit 1120-4, and/or the like. The data conversion circuit 1120-2 may receive image data from the controller 1120-1, and may compensate for the image data such that an image is displayed at desired or suitable luminance according to the characteristics of the electronic apparatus 1000 or a setting of a user or may convert the image data to reduce power consumption or compensate for afterimages. The gamma correction circuit 1120-3 may convert image data, a gamma reference voltage, and/or the like such that an image displayed on the electronic apparatus 1000 has desired or suitable gamma characteristics. The rendering circuit 1120-4 may receive image data from the controller 1120-1 and may render the image data in consideration of a pixel arrangement and/or the like of the display panel DP applied to the electronic apparatus 1000. At least one selected from among the data conversion circuit 1120-2, the gamma correction circuit 1120-3, and the rendering circuit 1120-4 may be integrated into another component (for example, the main processor 1110 or the controller 1120-1). At least one selected from among the data conversion circuit 1120-2, the gamma correction circuit 1120-3, and the rendering circuit 1120-4 may be integrated into a data driver DD to be described in more detail.

The memory 1200 may store one or more suitable types (kinds) of data, which are utilized by at least one component of the electronic apparatus 1000 (for example, the processor 1100 or the sensor module 1610), and input data or output data about instructions related thereto. The memory 1200 may include at least one selected from among the volatile memory 1210 and the non-volatile memory 1220.

The input module 1300 may receive instructions or data, which is to be utilized in the components of the electronic apparatus 1000 (for example, the processor 1100, the sensor module 1610, or the audio output module 1630), from an external source of the electronic apparatus 1000 (for example, a user or the external electronic apparatus 1020).

The input module 1300 may include a first input module 1310 to which an instruction or data is input from a user and a second input module 1320 to which an instruction or data is input from the external electronic apparatus 1020. The first input module 1310 may include a microphone, a mouse, a keyboard, a key (for example, a button), and/or a pen (for example, a passive pen or an active pen). The second input module 1320 may support a designated protocol that may be connected to the external electronic apparatus 1020 in a wired or wireless manner. According to one or more embodiments, the second input module 1320 may include a high-definition multimedia interface (HDMI), a universal serial bus (USB) interface, a secure digital (SD) card interface, and/or an audio interface. The second input module 1320 may include a connector that may be physically connected to the external electronic apparatus 1020, for example, an HDMI connector, a USB connector, an SD card connector, and/or an audio connector (for example, a headphone connector).

The display device 1 visually provides information to a user. The display device 1 may include the display panel DP, a scan driver GP, and the data driver DD. The display device 1 may further include a window, a chassis, and a bracket to protect the display panel DP.

The display panel DP may further include a light-emitting driver. The light-emitting driver outputs an emission control signal to the display panel DP in response to a control signal received from the controller 1120-1. The light-emitting driver may be formed separately from the scan driver GP or may be integrated into the scan driver GP.

The scan driver GP receives a control signal from the controller 1120-1 and outputs scan signals to the display panel DP in response to the control signal. For example, a control signal generated by the controller 1120-1 and transmitted to the scan driver GP may be a scan input signal for controlling the scan driver GP. The scan input signal may be an input signal applied to switching elements included in stages of the scan driver.

The data driver DD receives a control signal from the controller 1120-1, converts image data into analog voltages (for example, data voltages) in response to the control signal, and then outputs the data voltages to the display panel DP. For example, a control signal generated by the controller 1120-1 and transmitted to the data driver DD may be a data input signal for controlling the data driver DD.

The data driver DD may be integrated into another component (for example, the controller 1120-1). The above-described functions of the interface conversion circuit and the timing control circuit of the controller 1120-1 may also be integrated into the data driver DD.

The controller 1120-1 may generate a clock signal suitable for driving the scan driver GP. Each stage of the scan driver GP may be operated based on a clock signal corresponding to each stage.

The scan driver GP may generate a scan signal based on a scan input signal, a clock signal, and a scan input voltage. The scan signal may be transmitted to a pixel circuit, and a thin-film transistor included in the pixel circuit may be driven based on the scan signal. The scan signal may be transmitted to a gate included in the pixel circuit.

The display device 1 may further include a light-emitting driver, a voltage generation circuit, and/or the like. The voltage generation circuit may output one or more suitable voltages for driving the display panel DP.

The power module 1500 supplies power to the components of the electronic apparatus 1000. The power module 1500 may generate a gate driving voltage (for example, a gate high-voltage or a gate low-voltage) suitable for driving the scan driver GP.

For example, the power module 1500 may refer to a power generation unit, a power supply, and/or the like. For example, the power module 1500 may include a battery that is charged with a power voltage. The battery may include a non-rechargeable primary battery, a rechargeable secondary battery, and/or a fuel cell.

For example, the power module 1500 may include a power management integrated circuit (PMIC). The PMIC provides improved or optimized power to each of modules/devices described above and modules/devices to be described in more detail.

For example, the power module 1500 may include a wireless power transmission/reception member electrically connected to the battery. The wireless power transmission/reception member may include a plurality of coil-shaped antenna radiators.

The electronic apparatus 1000 may further include the embedded module 1600 and the external module 1700. The embedded module 1600 may include the sensor module 1610, the antenna module 1620, and the audio output module 1630. The external module 1700 may include the camera module 1710, a light module 1720 (e.g., a light source/supply), and the communication module 1730.

The sensor module 1610 may detect an input through a body of a user or an input through the pen of the first input module 1310 and may generate an electric signal or data value corresponding to the input. The sensor module 1610 may include at least one selected from among the fingerprint sensor 1610-1, the input sensor 1610-2, and/or a digitizer 1610-3.

The fingerprint sensor 1610-1 may generate a data value corresponding to a fingerprint of a user. The fingerprint sensor 1610-1 may include any one of an optical fingerprint sensor and a capacitive fingerprint sensor.

The input sensor 1610-2 may generate data values corresponding to coordinate information of the input through the body of the user or the input through the pen. The input sensor 1610-2 generates a change in electrostatic capacitance, which is caused by an input, as a data value. The input sensor 1610-2 may detect an input through the passive pen or may be to transmit or receive data to or from the active pen.

The input sensor 1610-2 may also measure a biosignal of blood pressure, moisture, body fat, and/or the like. For example, if (e.g., when) a user touches a sensor layer or sensing panel with a part of his or her body and does not move for a certain period of time, the input sensor 1610-2 may detect a biosignal based on a change in electric field caused by the part of his or her body and may output information desired or suitable by the user to the display device 1.

The digitizer 1610-3 may generate data values corresponding to coordinate information of the input through the pen. The digitizer 1610-3 generates an electromagnetic change amount, which is caused by an input, as a data value. The digitizer 1610-3 may detect an input through the passive pen or may be to transmit or receive data to or from the active pen.

At least one selected from among the fingerprint sensor 1610-1, the input sensor 1610-2, and the digitizer 1610-3 may be implemented as a sensor layer formed on the display panel DP through a substantially continuous process. The fingerprint sensor 1610-1, the input sensor 1610-2, and the digitizer 1610-3 may be arranged at an upper side of the display panel DP, and any one selected from among the fingerprint sensor 1610-1, the input sensor 1610-2, and the digitizer 1610-3, for example, the digitizer 1610-3, may be arranged at a lower side of the display panel DP.

At least two of the fingerprint sensor 1610-1, the input sensor 1610-2, and the digitizer 1610-3 may be formed to be integrated into one sensing panel through substantially the same process. If (e.g., when) at least two of the fingerprint sensor 1610-1, the input sensor 1610-2, and the digitizer 1610-3 are integrated into one sensing panel, the sensing panel may be arranged between the display panel DP and the window arranged above the display panel DP. According to one or more embodiments, the sensing panel may be arranged on the window, and a position of the sensing panel is not limited.

At least one selected from among the fingerprint sensor 1610-1, the input sensor 1610-2, and the digitizer 1610-3 may be embedded in the display panel DP. For example, at least one selected from among the fingerprint sensor 1610-1, the input sensor 1610-2, and the digitizer 1610-3 may be formed concurrently (e.g., simultaneously) through a process of forming elements (for example, light-emitting elements or transistors) included in the display panel DP.

In one or more embodiments, the sensor module 1610 may generate an electrical signal or data value corresponding to an internal or external state of the electronic apparatus 1000. The sensor module 1610 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The antenna module 1620 may include one or more antennas for transmitting or receiving signals or power to or from the outside. According to one or more embodiments, the communication module 1730 may be to transmit or receive a signal to or from an external electronic apparatus through an antenna suitable for a communication method. An antenna pattern of the antenna module 1620 may be integrated into one component of the display device 1 (for example, the display panel DP) or the input sensor 1610-2.

The audio output module 1630 may be a device for outputting an audio signal to the outside of the electronic apparatus 1000 and may include, for example, a speaker utilized for general purposes such as multimedia playback or record playback, and a receiver utilized exclusively for incoming calls. According to one or more embodiments, the receiver may be formed integrally with or separately from the speaker. A sound output pattern of the audio output module 1630 may also be integrated into the display device 1.

The camera module 1710 may capture a still image and/or a video. According to one or more embodiments, the camera module 1710 may include one or more selected from among lenses, image sensors, and/or image signal processors (ISPs). The camera module 1710 may further include an IR camera capable of measuring the presence or absence of a user, the position of the user, the gaze of the user, and/or the like.

The light module 1720 may provide light. The light module 1720 may include a light-emitting diode and/or a xenon lamp. The light module 1720 may operate in conjunction with the camera module 1710 or independently.

The communication module 1730 may support an establishment of a wired or wireless communication channel between the electronic apparatus 1000 and the external electronic apparatus 1020 and may support performance of communication through the established communication channel. The communication module 1730 may include one or both (e.g., simultaneously) of a wireless communication module/device, such as a cellular communication module, a short-range wireless communication module, and/or a global navigation satellite system (GNSS) communication module, and a wired communication module, such as a local area network (LAN) communication module and/or a power line communication module. The communication module 1730 may communicate with the external electronic apparatus 1020 through a short-range communication network such as Bluetooth, WiFi direct, and/or infrared data association (IrDA), or a long-range communication network such as a cellular network, the Internet, and/or a computer network (for example, a LAN or wide area network (WAN)). The above-described one or more suitable types (kinds) of the communication module 1730 may be implemented as one chip or separate chips.

The input module 1300, the sensor module 1610, the camera module 1710, and/or the like may be utilized to control the operation of the display device 1 in conjunction with the processor 1100.

The processor 1100 outputs instructions or data to the display device 1, the audio output module 1630, the camera module 1710, or the light module 1720 based on input data received from the input module 1300. For example, the processor 1100 may generate image data in response to input data applied through the mouse, the active pen, and/or the like to output the image data to the display device 1 or may generate instruction data in response to the input data to output the instruction data to the camera module 1710 or the light module 1720. If (e.g., when) input data is not received from the input module 1300 for a period of time, the processor 1100 may convert an operation mode of the electronic apparatus 1000 into a low power mode or sleep mode, thereby reducing power consumption of the electronic apparatus 1000.

The processor 1100 outputs instructions or data to the display device 1, the audio output module 1630, the camera module 1710, or the light module 1720 based on sensing data received from the sensor module 1610. For example, the processor 1100 may compare authentication data applied by the fingerprint sensor 1610-1 with authentication data stored in the memory 1200 and then may execute an application based on a comparison result. The processor 1100 may execute an instruction or output corresponding image data to the display device 1 based on sensing data detected by the input sensor 1610-2 or the digitizer 1610-3. If (e.g., when) a temperature sensor is included in the sensor module 1610, the processor 1100 may receive temperature data about a measured temperature from the sensor module 1610 and may further perform luminance correction and/or the like on an image data based on the temperature data.

The processor 1100 may receive measurement data about the presence or absence of a user, the position of the user, the gaze of the user, and/or the like from the camera module 1710. The processor 1100 may further perform luminance correction and/or the like on image data based on the measurement data. For example, the processor 1100 that has determined the presence or absence of a user through an input from the camera module 1710 may output image data, of which luminance is corrected through the data conversion circuit 1120-2 or the gamma correction circuit 1120-3, to the display device 1.

Some components of the components may be connected to each other through a communication method between peripheral devices, such as a bus, general purpose input/output (GPIO), a serial peripheral interface (SPI), a mobile industry processor interface (MIPI), or an ultra-path interconnect (UPI) link, to exchange signals (for example, instructions or data) with each other. The processor 1100 may communicate with the display device 1 through a mutually agreed interface. For example, the processor 1100 may utilize any one selected from among the above-described communication methods and is not limited to the above-described communication methods.

The electronic apparatus 1000 according to one or more suitable embodiments provided in the present document may be one of one or more suitable types (kinds) of apparatuses. The electronic apparatus 1000 may include, for example, at least one selected from among a portable communication device (for example, a smartphone), a computer device, a portable multimedia device, a portable medical device, a camera, a wearable device, and/or a home appliance device. The electronic apparatus 1000 according to one or more embodiments of the present disclosure is not limited to the devices described above.

In one or more embodiments, the display device 1 may include the display panel DP and the scan driver GP. The controller 1120-1 may generate a scan input signal suitable for driving the scan driver GP. The power module 1500 may generate a scan input voltage suitable for driving the scan driver GP under the control of the processor 1100 or controller 1120-1. For example, the scan input voltage may be a gate driving voltage.

The display panel DP may be divided into a display area DA in which pixel circuits are arranged and a peripheral area PA around the display area DA. As described above, an area in which an image is displayed may be the display area DA, and an area which is an area other than the display area DA and in which an image is not displayed may be the peripheral area PA.

The scan driver GP may be arranged in the peripheral area PA and may receive a scan input signal from the controller 1120-1 and receive a scan input voltage from the power module 500. The scan driver GP may generate or output a scan signal based on the scan input signal and/or the scan input voltage. The scan signal may be transmitted from the scan driver GP to the pixel circuit.

In one or more embodiments, the scan driver GP may include at least one capacitor. At least one capacitor may include one electrode and the other electrode. For example, one electrode may be a signal line that transmits at least one selected from among a scan input signal and a scan input voltage. For example, one electrode may be at least a portion of the signal line transmitting at least one selected from among a scan input signal and a scan input voltage. The signal line may also be, for example, an interconnect to which a scan input voltage is transmitted.

For example, the other electrode may overlap one electrode. The other electrode may overlap a signal line transmitting at least one selected from among a scan input signal and a scan input voltage. For example, the other electrode may overlap at least a portion of the signal line transmitting at least one selected from among a scan input signal and a scan input voltage.

In one or more embodiments, the peripheral area PA may include an interconnect arrangement area in which interconnects are arranged, and a circuit arrangement area which is positioned between the display area DA and the interconnect arrangement area and in which at least one transistor is arranged. For example, at least one capacitor may be arranged in the interconnect arrangement area. At least one capacitor may be arranged in the interconnect arrangement area.

In this way, in a display device, a method for manufacturing the display device, and an electronic apparatus including the display device according to the present disclosure, a third insulating layer VIA3 may be arranged on a second insulating layer VIA2, and third connection electrodes SD31 and SD32 may be arranged on the third insulating layer VIA3, thereby obtaining an effect of reducing a data load and a scan load.

In one or more embodiments, in the display device, the method for manufacturing the display device, and the electronic apparatus including the display device according to the present disclosure, the third insulating layer VIA3 which is a planarizing layer may be arranged on a second insulating layer VIA2, thereby improving diffused reflection characteristics of a connection electrode.

In one or more embodiments, in the display device, the method for manufacturing the display device, and the electronic apparatus including the display device according to the present disclosure, a thickness of an insulating layer VIA formed as an organic layer may be reduced to reduce outgassing, thereby improving the performance of a display device to be manufactured.

Due to the configuration of the display device, the optical characteristics of the display device may be improved. For example, the third insulating layer may be formed as a planarizing layer, so that the surface planarization may be achieved, and the electrical interference between the third insulating layer and its adjacent layer may also be reduced. Furthermore, if the pixel electrode is arranged on the third insulating layer, the adhesion to the pixel electrode PE may be improved. Furthermore, because the third insulating layer is arranged on the second insulating layer, and the third connection electrodes are arranged on the third insulating layer, an effect of reducing the data load and the scan load may be achieved.

In addition, an additional thin-film encapsulation layer having a multilayer structure may prevent or reduce cracks from forming. Furthermore, because the thickness of the utilized organic film may be reduced, thereby obtaining an effect of improving outgassing.

Each of one or more embodiments described above may be implemented independently, or the structures of each embodiment may be applied in combination to one or more embodiments.

While the present disclosure has been described with reference to one or more embodiments illustrated in the drawings, this is merely illustrative. It is to be understood that one or more suitable equivalent modifications and variations of one or more embodiments may be made by a person having ordinary skill in the art without departing from the spirit and scope of the present disclosure and their equivalents. Therefore, the true technical scope of protection of the present disclosure should be determined by the technical spirit of the appended claims. Accordingly, the true technical protection scope of the present disclosure should be defined by the technical spirit of the appended claims.

The display apparatus/device, the electronic apparatus/device, the manufacturing apparatuses thereof, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the one or more suitable components of the device may be formed on one integrated circuit (IC) chip or on separate IC chips. Further, the one or more suitable components of the device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components for performing the one or more suitable functionalities described herein. The computer program instructions are stored in a memory which may be implemented in a computing device utilizing a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

The specific implementations described in one or more embodiments are examples and do not limit the scope of one or more embodiments in any method. In one or more embodiments, unless “essential,” “important,” and/or the like are not specifically mentioned, it may not be a suitable component for the application of the disclosure.

In the specification (especially in the claims) of one or more embodiments, the use of the term “the” and similar indicating terms may correspond to both (e.g., simultaneously) singular and plural. In one or more embodiments, in the case where a range is described in the embodiment, because it includes the disclosure in which the individual values belonging to the range are applied, unless otherwise stated, it is the same as describing each individual value constituting the range in the detailed description. Finally, if (e.g., when) there is no explicit or contradictory description of operations constituting the method according to the embodiment, the operations may be performed in a suitable order. The embodiments are not necessarily limited to the order in which the operations are described. The use of all the examples or example terms in one or more embodiments is merely for describing one or more embodiments in more detail. Accordingly, the scope of one or more embodiments may not be limited by the examples or example terms, unless limited by the claims. In one or more embodiments, those skilled in the art may recognize that one or more suitable modifications, combinations, and changes may be configured according to design conditions and factors within the scope of the appended claims or equivalents thereof.

According to the disclosure, there may be provided a display device having improved optical characteristics, a method for manufacturing the display device, and an electronic apparatus including the display device.

However, the effects are only for illustration, and the effects of the disclosure are not limited thereto.

What is claimed is:

1. A display device comprising:
a substrate having a display area and a peripheral area outside the display area;
a first insulating layer which is on a first connection electrode on the substrate and is in the display area as well as the peripheral area on the substrate;
a second connection electrode on the first insulating layer;
a second insulating layer on the second connection electrode;
a third insulating layer on the second insulating layer; and
a third connection electrode on the third insulating layer.

2. The display device of claim 1, wherein the third insulating layer is a planarizing layer.

3. The display device of claim 1, further comprising a fourth insulating layer on the third insulating layer.

4. The display device of claim 3, wherein the fourth insulating layer is a planarizing layer.

5. The display device of claim 1, further comprising a pixel-defining layer on the third insulating layer and having at least two openings defined therein.

6. The display device of claim 5, further comprising:
a first pixel electrode of which a central portion is exposed by one opening of the at least two openings of the pixel-defining layer and which is on the third insulating layer, at least a portion of the first pixel electrode being in contact with the third insulating layer; and
a second pixel electrode of which a central portion is exposed by another opening of the at least two openings of the pixel-defining layer and which is on the third insulating layer, the second pixel electrode being not in contact with the third insulating layer.

7. The display device of claim 5, wherein the pixel-defining layer is a black pixel-defining layer.

8. A display device comprising:
a substrate having a display area and a peripheral area outside the display area;
a first insulating layer which is on a first connection electrode on the substrate and is in the display area as well as the peripheral area on the substrate;
a second connection electrode on the first insulating layer;
a second insulating layer on the second connection electrode;
a third insulating layer on the second insulating layer and to be planarized;
a pixel-defining layer on the third insulating layer and having at least two openings defined therein; and
a first pixel electrode and a second pixel electrode of which central portions are exposed by the least two openings of the pixel-defining layer.

9. The display device of claim 8, wherein a thickness of an insulating layer positioned at a position overlapping a portion at which the first pixel electrode is exposed is different from a thickness of the insulating layer positioned at a position overlapping a portion at which the second pixel electrode is exposed.

10. The display device of claim 8, wherein at least a portion of the first pixel electrode is in contact with the third insulating layer.

11. The display device of claim 10, further comprising an emission layer on the first pixel electrode and configured to emit green light.

12. The display device of claim 8, wherein the second pixel electrode is positioned not to be in contact with the third insulating layer.

13. The display device of claim 12, further comprising an emission layer on the second pixel electrode and configured to emit red or blue light.

14. The display device of claim 8, further comprising:
a third connection electrode on the third insulating layer; and
a fourth insulating layer on the third connection electrode.

15. The display device of claim 14, wherein the fourth insulating layer is a planarizing layer.

16. A method comprising:
preparing a substrate;
forming a first connection electrode on the substrate;
forming a first insulating layer on the first connection electrode;
forming a second connection electrode on the first insulating layer;
forming a second insulating layer on the second connection electrode;
forming a third insulating layer on the second insulating layer; and
forming a third connection electrode on the third insulating layer,
wherein the method is a method for manufacturing a display device.

17. The method of claim 16, wherein the forming of the third insulating layer comprises planarizing the third insulating layer.

18. The method of claim 16, further comprising forming a fourth insulating layer on the third connection electrode.

19. The method of claim 18, further comprising:
forming a first pixel electrode and a second pixel electrode on the fourth insulating layer; and
forming a pixel-defining layer having openings configured to expose central portions of the first pixel electrode and the second pixel electrode.

20. The method of claim 19, wherein a distance from an uppermost portion of the pixel-defining layer to a portion at which the first pixel electrode is exposed is different from a distance from the uppermost portion of the pixel-defining layer to a portion at which the second pixel electrode is exposed.

21. An electronic apparatus comprising:
a controller configured to generate a scan input signal;
a power supply configured to generate a scan input voltage; and
a display device partitioned into a display area in which a pixel circuit is located and a peripheral area positioned outside the display area and comprising a pad area,
wherein the display device comprises:
a substrate having a display area and a peripheral area outside the display area;
a first insulating layer which is on a first connection electrode on the substrate and is in the display area as well as the peripheral area on the substrate;
a second connection electrode on the first insulating layer;
a second insulating layer on the second connection electrode;
a third insulating layer on the second insulating layer; and
a third connection electrode on the third insulating layer.
